(19) United States
(12) Patent Application Publication
(10) Pub. No.: US 2026/0160963 A1
(43) Pub. Date: Jun. 11, 2026

(54) PHOTONIC DEVICE COMPRISING A MICRO-TUBE ELECTRO-OPTICAL INTERCONNECTOR

(71) Applicant: COMMISSARIAT À L'ENERGIE ATOMIQUE ET AUX ENERGIES ALTERNATIVES, PARIS (FR)

(72) Inventor: Abdenacer AIT MANI, GRENOBLE (FR)

(21) Appl. No.: 19/413,927

(22) Filed: Dec. 9, 2025

(30) Foreign Application Priority Data
Dec. 9, 2024 (FR) 2413677

(51) Int. Cl. G02B 6/42; G02B 6/12; G02B 6/136; G02B 6/43; H10W 20/00; H10W 20/20

(52) U.S. Cl. CPC G02B 6/4274; G02B 6/136; G02B 6/4246; G02B 6/4257; G02B 6/43; H10W 20/0242; H10W 20/2125; H10W 20/213; H10W 20/217; G02B 2006/12176

(57) ABSTRACT

A photonic device includes an emitter component, to emit at least one emission signal including an optical signal component, a receiver component, and an interconnect component between the emitter component and the receiver component, the interconnect component including at least one micro-tube designed to transmit the optical signal component coming from the emitter component to the receiver component. A micro-tube includes a wall and an internal medium designed to propagate the optical signal component, surrounded by the wall of the micro-tube, the wall being designed to separate the internal medium and an ambient medium wherein the photonic device is immersed.

### CROSS-REFERENCE TO RELATED APPLICATION

This application claims priority to foreign French patent application No. FR 2413677, filed on Dec. 9, 2024, the disclosure of which is incorporated by reference in its entirety.

### FIELD OF THE INVENTION

The present invention relates in general to the field of photonic interconnects, and in particular to a photonic device comprising an electro-optical interconnector obtained from at least one micro-tube designed to transmit at least one optical component of a signal, and to a process for fabricating such a device.

### BACKGROUND

Photonic interconnects are commonly used in applications for the acquisition, transmission and processing of information in integrated circuits and photonic integrated circuits, in order to improve their performance and packaging.

In existing photonic interconnect systems, it is known practice to make holes in substrates commonly used in microelectronics. These holes, also called vias, may be through silicon vias (TSV) or through glass vias (TGV). These holes may be produced so as to form light guides associated with optical properties suitable for a specific application and for the wavelengths used, as described in patent U.S. Pat. No. 10197730 B1 or in patent application WO 2019/048653 A1.

However, known photonic interconnect solutions have high fabrication costs and do not take into account the low tolerance of optical signals to misalignments. This is particularly the case for the device described in the article “3D optical coupling techniques on polymer waveguides for wafer and board level integration” by S. Lüngen et al., IEEE 67th Electronic Components and Technology Conference (ECTC), Orlando, FL, USA, 2017, pp. 1612-1618, in which the vias are combined with mirrors so as to direct light, thereby making the device extremely complex from a technological point of view and not particularly robust.

These solutions may also exhibit parasitic optical communications (or optical loss, optical leaks) between the various vias of one and the same interconnector, thus generating an effect known as crosstalk.

The problem relating to optical alignments has been studied in the article “Optical Vertical Interconnect and Integration Based on Silicon Carrier” by F. Liu et al., 13th International Conference on Electronic Packaging Technology & High Density Packaging, Guilin, China, 2012, pp. 97-100, in which the photonic interconnector comprises an array of optical fibres. That article proposes an approach in which each fibre is inserted into a via such that the vias have more of a role of “mechanical guide” than a role of “light guide”. This also results in limited miniaturization capabilities for the photonic device.

The problem relating to optical crosstalk has been addressed in patent application US 2020/0235038 A1, in which the fabrication of the photonic interconnector comprises etching operations in order to form cavities between the TSV or TGV structures so as to isolate them optically from one another. The fabrication also comprises an operation of applying a cavity sealing material based on epitaxial growth of heterogeneous material requiring high annealing temperatures. However, such solutions implement highly complex fabrication processes, associated with very expensive microelectronic technologies.

There is thus a need for an optical interconnector that makes it possible to improve optical signal transmission performance between an emitter and a receiver, taking into account notably the low tolerance of photons to misalignments, and for an improved process for fabricating a resulting photonic device.

### SUMMARY OF THE INVENTION

The present invention aims to improve the situation by proposing a photonic device comprising an emitter component, configured to emit at least one emission signal comprising an optical signal component, a receiver component, and an interconnect component between the emitter component and the receiver component. The interconnect component comprises at least one micro-tube designed to transmit the optical signal component coming from the emitter component to the receiver component, the at least one micro-tube comprising a wall and an internal medium designed to propagate the optical signal component, surrounded by the wall of the micro-tube, the wall being designed to separate the internal medium and an ambient medium in which the photonic device is immersed.

In some embodiments, the photonic device may comprise at least one emission coupling element configured to couple the emitter component and one end of a micro-tube.

The photonic device may comprise at least one reception coupling element configured to couple the receiver component and one end of a micro-tube.

Advantageously, the at least one emission signal may furthermore comprise an electrical signal component, the wall of a micro-tube comprising at least one metal part configured to propagate the electrical signal component coming from the emission component to the receiver component.

According to some aspects of the invention, the interconnect component may furthermore comprise an intermediate substrate comprising at least one micro-via in association with each micro-tube, the at least one micro-via being designed to transmit the optical signal component coming from the emitter component to the receiver component.

The at least one emission signal may furthermore comprise an electrical signal component, and advantageously, the at least one micro-via may comprise a metal wall configured to propagate the electrical signal component coming from the emitter component to the receiver component.

In some embodiments, the at least one micro-tube may comprise a filler material chosen so as to optimize the propagation of the optical component of the signal to be transmitted.

The at least one micro-via may comprise a filler material chosen so as to optimize the propagation of the optical component of the signal to be transmitted.

The dimensions of the interconnect component may be of the order of a few micrometres to a few tens of micrometres.

In some embodiments, the interconnect component may furthermore comprise a photonic interposer, the at least one micro-tube extending longitudinally between the emitter component and the photonic interposer, and/or between the photonic interposer and the receiver component.

The present invention also provides a process for fabricating the photonic device. The process comprises the following steps:
preparing an emitter component capable of emitting at least one emission signal comprising an optical signal component, and preparing a receiver component,
fabricating an interconnect component comprising at least one micro-tube, and
assembling the interconnect component between the emitter component and the receiver component.

The process comprises fabricating the at least one micro-tube, a micro-tube being capable of transmitting said optical signal component coming from the emitter component to the receiver component, the at least one micro-tube comprising a wall and an internal medium capable of propagating the optical signal component, surrounded by the wall of the micro-tube, the wall separating the internal medium and an ambient medium in which the photonic device is immersed.

In some embodiments, the assembly step may comprise coupling the emitter component and/or the receiver component to one end of a micro-tube using at least one emission coupling element and/or at least one reception coupling element, the coupling comprising cold-inserting the at least one micro-tube of the interconnect component into the at least one emission and/or reception coupling element.

Advantageously, the step of fabricating the interconnect component may comprise:
providing at least one support substrate,
fabricating the at least one micro-tube, on a support face of the support substrate,
implementing at least one etching of the support substrate perpendicularly so as to form at least one micro-via, from a back face of the support substrate to the support face, the at least one etching being carried out so as to open onto the inside of the at least one micro-tube.

The at least one emission signal furthermore comprises an electrical signal component, and the step of fabricating the interconnect component may comprise depositing a metal layer on the wall of a micro-tube so that the wall comprises at least one metal part capable of propagating the electrical signal component coming from the emitter component to the receiver component.

The embodiments of the invention thus provide a photonic interconnector comprising at least one micro-tube for improving optical signal transmission performance between an emitter and a receiver, via low-loss data transport.

They also provide a dual-function parallel interconnect solution allowing the transmission of what is referred to as ‘electrical’ information and what is referred to as ‘optical’ information between substrates.

The embodiments of the invention advantageously provide an affordable solution in terms of cost, the fabrication and assembly of the photonic interconnector being particularly compatible with large-scale fabrication, the unit cost of a micro-tube thereby being economically inexpensive.

Fabricating matrices of micro-tubes, on a microelectronics platform for example, makes it possible to guarantee the formation of objects with high density (very small pitch) and with micrometric dimensions, ultimately generating dense and compact photonic devices for parallel data transmission of a large amount of electro-optical information and without crosstalk.

The embodiments also make it possible to facilitate and speed up the process for fabricating such a device. Cold-insertion assembly also makes it possible to guarantee the electronic integrity of the components of the device, while at the same time applying compensation for significant planarity defects between the components to be assembled. This cold assembly also allows precise alignment of the components opposite, avoiding stresses related to differences in coefficient of thermal expansion (CTE) between various materials forming the components to be assembled. Such stresses may often be high in fabrication processes using assemblies at temperature (or at high temperature).

The embodiments advantageously provide high-performance devices that combine the use of micro-tubes and TSVs, or that allow coupling to pre-established arrays of guides.

### BRIEF DESCRIPTION OF THE DRAWINGS

Other features, details and advantages of the invention will become apparent on reading the description provided with reference to the appended drawings, which are given by way of example.

FIG. 1 is a diagram showing a photonic device, according to some embodiments of the invention.

FIG. 2 shows diagrams 2[a] and 2[b] showing an emissive component, according to some embodiments of the invention.

FIG. 3 shows diagrams 3[a] and 3[b] showing a receiver component, according to some embodiments of the invention.

FIG. 4 shows diagrams 4[a] and 4[b] showing a micro-tube of an interconnect component, according to some embodiments of the invention.

FIG. 5 is a diagram showing a photonic device, according to some embodiments of the invention.

FIG. 6 is a diagram showing a photonic device, according to some embodiments of the invention.

FIG. 7 is a diagram showing a photonic device, according to some embodiments of the invention.

FIG. 8 shows diagrams 8[a] and 8[b] showing a micro-via of an interconnect component, according to some embodiments of the invention.

FIG. 9 is a diagram showing a photonic device, according to some embodiments of the invention.

FIG. 10 is a flowchart showing steps of a process for fabricating a photonic device, according to some embodiments of the invention.

FIG. 11 shows flowcharts 11[a] and 11[b] showing sub-steps of the process for fabricating a photonic device, according to some embodiments of the invention.

FIG. 12 is a flowchart showing sub-steps of the process for fabricating a photonic device, according to some embodiments of the invention.

FIG. 13 shows diagrams 13[a] and 13[b] showing an interconnect component in the process of being fabricated, according to some embodiments of the invention.

FIG. 14 shows diagrams 14[a] and 14[b] showing an interconnect component in the process of being fabricated, according to some embodiments of the invention.

FIG. 15 shows diagrams 15[a] and 15[b] showing an interconnect component in the process of being fabricated, according to some embodiments of the invention.

FIG. 16 shows diagrams 16[a] and 16[b] showing an interconnect component in the process of being fabricated, according to some embodiments of the invention.

Identical references have been used in the figures to denote identical or similar elements. For the sake of clarity, the elements shown are not to scale.

Moreover, in the remainder of the description, unless indicated otherwise, the terms “substantially” and “generally” mean “to within plus or minus 10%”.

### DETAILED DESCRIPTION

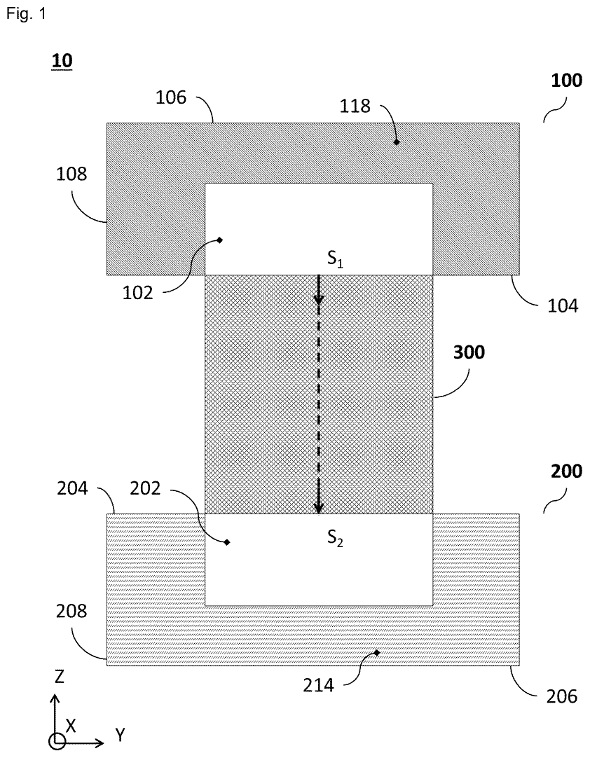

FIG. 1 schematically shows a photonic device 10 comprising an emitter component 100, a receiver component 200 and an interconnect component 300 between the emitter component 100 and the receiver component 200, according to some embodiments of the invention.

The photonic device 10 (also called a ‘photonic interconnect device’, ‘transmission device’, or more simply ‘device’) is configured to propagate information using transmission of optical signals (or photonic signals) from an optical source to an optical receiver. Such a device may be implemented, for example and without limitation, in the form of a high-speed data transfer vertical connection device, or else a planar transceiver device allowing optical signals and/or electro-optical signals to be converted or communicated. The photonic device 10 may be integrated into a system 1, for example with other chips, or other elements of discrete circuits, integrated circuits and/or signal processing devices. The system 1, comprising the photonic device 10, may be used in numerous applications, such as applications for the acquisition, transmission and processing of information. The system 1 may be, for example and without limitation, a motherboard used in telecommunications systems, in imaging systems, in industrial systems (cybersecurity, or manufacturing for example), in systems relating to the banking or fiscal field, or even in computing systems.

In the remainder of the description, it will be considered, by way of simplification, that the term “signal” may correspond to an optical signal and/or to an electro-optical signal.

An electro-optical signal comprises an optical signal component and an electrical signal component, such that an electro-optical signal carries, together, information referred to as ‘optical information’ and information referred to as ‘electrical information’. Similarly, an optical signal comprises only an optical signal component, that is to say an optical signal carries only optical information.

Moreover, as used here, an “optical signal” refers to a continuous wave or results from one or more non-coherent or coherent pulses of light coming from an optical source (or emissive optical source), such as a laser beam. The electromagnetic wave (or beam) carrying the optical signal is characterized notably by a given wavelength λ (that is to say one relating to a specific frequency band or optical frequency band). The electromagnetic wave may also be characterized by a given polarization and phase. An optical frequency band corresponds to a range of optical frequencies. An optical frequency band may correspond to wavelengths in the infrared (IR) range. For example and without limitation, an optical frequency band may correspond to wavelengths equal to 850 nm, to 1300 nm, or else to wavelengths typically between 1530 nm and 1565 nm (for example 1550 nm). Such an optical frequency band, defined in the near-infrared or mid-infrared, may be chosen because of the harmlessness of an IR signal to the eye and/or the ease of producing such a signal. An optical frequency band may also correspond to wavelengths in the visible range. For example and without limitation, an optical frequency band may correspond to wavelengths equal to 450 nm, 532 nm, or else 632 nm. Such a visible optical frequency band may be chosen in cases of high-speed optical information transmission. The emitter component 100 (also called a ‘photonic emitter component’, ‘source component’, ‘emissive substrate’, or else ‘emissive matrix’) may comprise one or more emission zones 102 for emitting a signal denoted S₁, according to some embodiments of the invention. Advantageously, the emitter component 100 may comprise a plurality N of emission zones 102-n each configured to emit a signal S₁ₙ, “n” being the index corresponding to the n^{th} emission zone of the emitter component 100. The index “n” is therefore an integer between 1 and N, the value of N being an integer greater than or equal to 1.

Furthermore, the receiver component 200 (also called a ‘photonic receiver component’, ‘reception component’, ‘receiver substrate’, or else ‘receiver matrix’) may comprise one or more reception zones 202 for receiving a signal denoted S₂, according to some embodiments of the invention. Advantageously, the receiver component 200 may comprise a plurality M of reception zones 202-m each configured to receive a signal S₁ₘ, “m” being the index corresponding to the m^{th} reception zone of the receiver component 200. The index “m” is therefore an integer between 1 and M, the value of M being an integer greater than or equal to 1.

In the example of FIG. 1, the emitter 100 comprises an emission zone 102 and the receiver 200 comprises a single reception zone 202.

Advantageously, the transmission device 10 may for example be defined in a reference system (X, Y, Z). The emitter component 100 may have a generally planar structure, defined in the plane (X, Y), associated with the reference system (X, Y, Z) of the device, and orthogonal to the axis Z. The emitter component 100 may thus generally extend in the plane (X, Y). In particular, the emitter component 100 may comprise a first face 104 (also called an ‘emission face’) and a second face 106 opposite the first face 104. The first and second faces may be substantially parallel to one another and defined in the plane (X, Y), as shown in FIG. 1. The first and second faces may be connected by an edge 108, such an edge being of small width compared to the length of the component 100 along the axis Y or X. The first and second faces of the emitter component 100 may have any geometrical shape and variable dimensions in the plane (X, Y).

The receiver component 200 may have a substantially planar structure, and generally extend in the plane (X, Y). The receiver component 200 may comprise a first face 204 (also called a ‘reception face’) and a second face 206 opposite the first face 204. The first and second faces may be substantially parallel to one another, defined in the plane (X, Y), and be connected by an edge 208, such an edge being of small width compared to the length of the component 200 along the axis Y or X. The first and second faces of the receiver component 200 may have any geometrical shape and variable dimensions in the plane (X, Y).

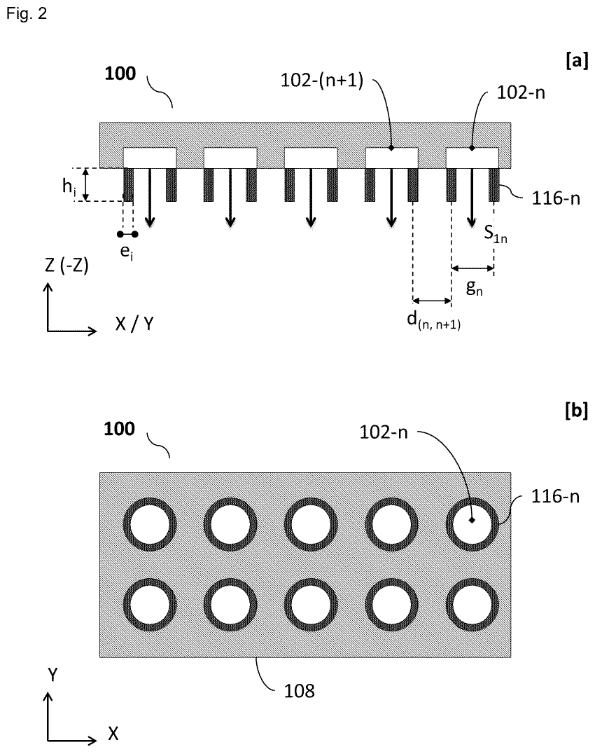

FIG. 2 shows two diagrams 2[a] and 2[b], respectively in the plane (X, Z) and in the plane (X, Y), of the emitter component 100, according to some embodiments of the invention. In the embodiments of FIG. 2, the emitter component 100 comprises a plurality of N emission zones 102-n. Each emission signal S₁ₙ originating from an emission zone 102-n may be emitted along a signal propagation direction that is generally parallel to the normal axis Z of the emitter component 100.

The optical component of an optical or electro-optical emission signal S₁ₙ to be transmitted may be associated with an emission optical frequency band denoted λ₁ₙ. In the case of a transmission device 10 associated with a plurality of emission zones 102-n, the optical components of the emission signals S1n may be associated with a single frequency band or, alternatively, with multiple mutually distinct frequency bands.

An emission zone 102-n may be spaced from another emission zone 102-(n+1) by a separation distance, denoted d_{(n, n+1)}. Such a separation distance d_{(n, n+1)} (also called a ‘spacing’) may be defined based on the geometry or distribution configuration of the various zones and at least a minimum separation distance between emission zones. The distances d_{(n, n+1)} may be of the order of a few micrometres to a few hundred micrometres.

As a variant, the distribution of emission zones may be determined with a pitch that may be defined based on the separation distance d_{(n, n+1)} for example.

According to some embodiments, the plurality of emission zones 102-n may be arranged in a regular matrix configuration in the plane (X, Y) on the emission face 104 of the emitter component 100 as shown as an example in diagrams 2[a] and 2[b] of FIG. 2. This regular matrix configuration may be defined by a single separation distance d_{(n, n+1)} between the various emission zones, considered in pairs, of the emitter component 100. The regular matrix configuration of the spatial distribution of emission zones 102-n may have any geometrical structure.

As an alternative, the positions of the emission zones 102-n may be arranged independently of one another, in an irregular, pseudo-random or even random distribution of emission zones. For example and without limitation, an irregular distribution of the plurality of emission zones may correspond to an emission component 102 comprising at least a first set of emission zones, defined with a first zone spacing d_{1(n, n+1)}, and a second set of emission zones, defined with a second zone spacing d_{2(n, n+1)}. For example, the first set may correspond to emission zones denser than the second set, the first spacing then being equal to a value less than the second spacing. Such an irregularity in the distribution of the emission zones in the plane (X, Y) is applied in the case of using different kinds of emission zones (that is to say in the case of hybrid sources). For example, the first set of emission zones may correspond to sources coming from a CMOS driver substrate, while the second set of emission zones may correspond to emissive elements added (a posteriori) to this same driver substrate to form the emission component 102. According to this example, the optical sources of a CMOS chip and the emissive elements may for example be of different sizes, and the various spacings of zones between the two sets may be determined such that the density of the sources of the first set is equivalent to the density of the sources of the second set.

In some embodiments, an emission zone 102-n (or 102) may comprise what is referred to as an ‘integrated’ emission source. Such an emission source may be integrated into the component 100 during the fabrication of the emissive substrate. The emission source may notably comprise an optical source configured to emit the optical component of a signal S₁ₙ associated with the emission zone 102-n. The optical source of the integrated emission source may be, for example and without limitation, a micro-LED (also denoted ‘MLED’ or ‘μLED’), a mini LED, an OLED, or any other light-emitting or laser-emitting source. The optical source of the integrated emission source may also be a vertical-cavity surface-emitting laser (VCSEL) optical source, configured to emit an optical signal of wavelength λ typically equal to 850 nm.

In some embodiments, an integrated emission zone 102-n of the emission component 102 may be configured to emit the electrical component of a signal S₁ₙ. For example, an integrated emission zone 102-n may comprise an electrical source element, such as an electrically conductive pad, adjacent to (that is to say positioned close to) the integrated optical source. The electrical component of a signal S₁ₙ may then be generated so as to travel from the electrical source element to the reception component 202 (via a micro-tube). In addition, at least part of the electrical component of a signal S₁ₙ may be used as a localized power source for supplying power to the integrated optical source. For example and without limitations, on a CMOS chip or on a photonic interposer, matrices of micro LEDs or matrices of VCSEL optical sources may be driven by hybridization, that is to say by hybrid optical and electrical signals.

Those skilled in the art will readily understand that the expression “electrical component of an electro-optical signal” refers to a bias voltage suitable for being supplied to optical sources or for travelling to a reception component 202. Furthermore, such an electrical component may be designed to transport electrical information from the emission component 102 to the reception component 202.

In other embodiments, the emitter component 100 may comprise one or more optical emission sources 110 that are said to be ‘remote’ (not shown in the figures). In such embodiments, the emitter component 100 may be equipped with an array 112 of optical waveguides (not shown in the figures) connecting the one or more optical emission sources 110 to the emission zone 102 of the emitter component 100, if a single emission zone is used, or to at least some of the emission zones 102-n of the emitter component 100, if multiple emission zones are used. A remote optical emission source 110 (one in and/or on the emissive substrate for example) is configured to emit the optical component of the one or more signals S₁ₙ propagating in the array of optical waveguides 112 to the emission zones. The array of optical waveguides 112 may also be a planar array extending substantially in the plane (X, Y).

Advantageously, the emitter component 100 may comprise one or more electrical emission sources 114 (not shown in the figures) and be equipped with an array 116 of electrical connections (not shown in the figures) electrically connecting the one or more electrical emission sources 114 to the emission zone 102 or to the emission zones 102-n for emitting electro-optical signals S₁ₙ.

Moreover, at least part of the electrical component of an electro-optical signal S₁ₙ to be emitted by an emission zone 102-n may correspond, for example and without limitation, to a power supply signal (that is to say an electric current) designed to supply power to and/or drive an integrated optical source of the emission zone 102-n.

An emission zone 102-n may be characterized by a geometry of a specific shape defined in the plane (X, Y). An emission zone 102-n may also be characterized by a quantity denoted g₁ₙ relating to the size of the zone on the emission face 104. The shape geometry (also called ‘emission geometry’ here) of a zone, and its associated quantity g₁ₙ, may depend on the nature of the emission zone 102-n used (that is to say the technological choice and/or the integrated or remote implementation used for the emission sources). For example, the geometry of the emission sources 102-n (also called ‘emission geometry’), on the face 104, may be circular, as shown in diagram 2[b] of FIG. 2. In the case of a circular emission geometry, the quantity g₁ₙ may correspond to the diameter of the circular shape representing the emission source. Those skilled in the art will readily understand that the invention is not limited to circular emission geometries, and may comprise other geometrical shapes such as, for example and without limitation, a square, rectangular, triangular, elliptical, trapezoidal, hexagonal, polygonal, etc. emission geometry. The one or more quantities g₁ₙ associated with the emission zones of the emitter component 100 may be for example of the order of a few micrometres to a few hundred micrometres.

Advantageously, the emitter component 100 may comprise a material 118, called an ‘emission support material’, compatible with the processes of integrating the (integrated or remote) signal emission sources and/or with the processes associated with microelectronic fabrication. For example and without limitation, the emission support material 118 may be any semiconductor material, such as for example a wafer or part of a wafer, the wafer possibly being made of silicon, germanium, gallium arsenide (AsGa), indium phosphide (InP), crystalline silicon or the like. An emission support material 118 may also be formed from any non-semiconductor material, such as, for example and without limitations, glass, pyrex and ceramics. Such a non-semiconductor material may advantageously be used in the embodiments in which the emission sources 110 are remote.

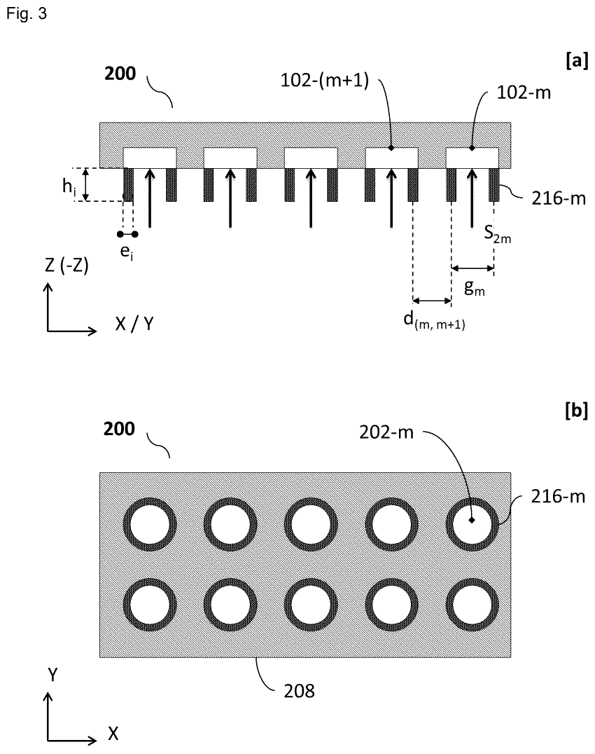

FIG. 3 shows two diagrams 3[a] and 3[b], respectively in the plane (X, Z) and in the plane (X, Y), of the receiver component 200, according to some embodiments of the invention. In the embodiments of FIG. 3, the receiver component 200 comprises a plurality of M reception zones 102-m.

Each reception zone 202-m of the receiver component 200 is associated with (or connected to) at least one specific emission zone 102-n of the emitter component 100.

The reception zones 202-m of the receiver component 200 are each designed to receive a signal S₂ₘ coming from a direction substantially parallel to the normal axis Z (perpendicular to the plane (X, Y)). The optical component of a received (optical or electro-optical) signal S₂ₘ may be associated with a reception optical frequency band denoted λ₂ₘ. In the transmission device 10, the optical components of the signals S₂ₘ may be associated with a single frequency band or, alternatively, with multiple distinct frequency bands.

A reception zone 202-m may be spaced from another reception zone 202-(m+1) by a separation distance d_{(m, m+1)}. Such a separation distance d_{(m, m+1)} (corresponding to a ‘spacing’) may be defined according to the distribution of the zones, starting from a minimum separation distance between reception zones. In some embodiments, the separation distance may be of the order of a few micrometres to a few hundred micrometres. In particular, the distance d_{(m, m+1)} may be equal to an associated distance d_{(n, n+1)}, corresponding to an emission zone 102-n.

The reception zones 202-m may for example be arranged in a regular matrix configuration on the reception face 204 of the receiver component 200, as shown in the example of diagrams 2[a] and 2[b] of FIG. 2. Such a regular matrix configuration of the distribution of zones may have any suitable geometrical structure.

As an alternative, the reception zones 202-m may for example be arranged irregularly (that is to say with variable zone spacings). For example and without limitation, an irregular distribution of the plurality of reception zones may correspond to a reception component 202 comprising at least a first set of reception zones, defined with a first zone spacing, and a second set of reception zones, defined with a second zone spacing.

In some embodiments, the reception zone 202-m (or 202) may comprise a photodetector component configured to detect the optical component of an optical and/or electro-optical signal S₂ₘ to be received. For example and without limitation, such a component may be a photodiode or any other photonic sensor, said to be ‘integrated’ during the fabrication of the receiver substrate.

Advantageously, the electrical component of an electro-optical signal S₂ₘ received by a reception zone 202-m may correspond to electrical information to be transmitted to the receiver component 200. As an alternative, such a component may correspond to a power supply signal (that is to say an electric current) designed to supply power to and/or drive the photodetector component of the zone 202-m.

In some exemplary embodiments, the receiver component 200 may comprise one or more acquisition units 210 configured to acquire the optical component of the one or more received signals S₂. The receiver component 200 may also be equipped with an array 212 of optical waveguides (not shown in the figures) connecting a reception zone 202-m or at least some of the reception zones 202-m to the acquisition units 210 (not shown in the figures), which are said to be ‘remote’, of the receiver component 200. The array of reception waveguides 212 may be a planar array extending substantially in the plane (X, Y).

In some embodiments, the emitter component 100 and/or the receiver component 200 equipped with arrays of optical waveguides may be discrete circuits, photonic and/or electrical chips or integrated circuits, or else passive or active interposer circuits.

In some exemplary embodiments, the electrical component of an electro-optical signal may be used to drive modulation of the wavelength, at emission, during propagation and/or at reception, of the optical component of the signal.

A reception zone 202-m may be characterized by a specific geometry defined in the plane (X, Y) and by a quantity denoted g₂ₘ relating to the size of the reception zone on the reception face 204. Such a geometry, called a ‘reception geometry’, and the associated quantity g₂ₘ may depend notably on the nature of the reception zone used (that is to say on the technological choice and/or on the integrated or remote implementation of the reception zone). For example and without limitation, the geometry of a reception zone may be circular in the plane (X, Y), as shown in diagram 3[b] of FIG. 3, the quantity g₂ₘ then corresponding to the diameter of the circular shape. Those skilled in the art will readily understand that the geometry of the reception zones 102-m is not limited to a circular shape, and may comprise any other suitable geometrical shape, such as, for example and without limitation, a square, rectangular, triangular, elliptical, trapezoidal, hexagonal, polygonal, etc. shape. In some embodiments, the size of the reception zone g₂ₘ may be of the order of a few micrometres to a few hundred micrometres.

Advantageously, the receiver component 200 may comprise a material 214, called a ‘reception support material’, compatible with the processes for integrating photodetector components and/or (integrated or remote) signal acquisition units and/or with processes associated with microelectronic fabrication, for example using hybridization tools available in microelectronic packaging technologies. In particular, the reception support material 214 may be any suitable semiconductor material, such as for example a wafer or part of a wafer, the wafer possibly being made of silicon, germanium, gallium arsenide (AsGa), indium phosphide (InP), crystalline silicon or the like. A reception support material 214 may also be formed from any non-semiconductor material, such as for example glass, pyrex and ceramics. Such a non-semiconductor material may advantageously be used in the embodiments in which the acquisition units are remote.

The one or more signals to be transmitted through the transmission device 10 may be emitted from the emission face 104 of the emitter component 100 (signals S₁ₙ), and received by the reception face 204 of the receiver component 200 (signals S₂ₘ), the one or more signals having been propagated in the interconnect component 300 between the two faces 104 and 204 of the device 10.

The interconnect component 300 (also called an ‘optical interconnector’, ‘photonic interconnector’, or else ‘electro-optical interconnector’) may comprise one or more signal propagation micro-tubes 310. In some embodiments, the interconnect component 300 may comprise a plurality P of micro-tubes 310-p (also called ‘interconnect pads’), “p” being the index corresponding to the p^{th} micro-tube of the interconnect component 300. The index “p” is therefore an integer between 1 and P, and the value of P is an integer greater than or equal to 1.

Advantageously, a micro-tube 310-p may be configured to transmit at least one signal coming from an emission zone 102-n of the emitter component 100 to the receiver component 200 as at least one resulting signal, received by a reception zone 202-m of the receiver component 200.

In particular, a signal propagation micro-tube 310-p may be configured to transmit a signal S₁ₙ coming from the emission zone 102-n of the emitter component 100 to the receiver component 200 as a resulting signal S₂ₘ, received by the reception zone 202-m. The micro-tubes 310-p may correspond to communication channels transporting optical information between the emitter component 100 and the receiver component 200.

In the remainder of the description, reference will be made mainly to a number M of reception zones 202-m equal to the number N of emission zones 102-n, for ease of understanding of the invention and by way of simplification. In these exemplary embodiments, by way of simplification, the index “m” associated with a reception zone 202-m will then be assimilated to the index “n” associated with an emission zone 102-n. However, those skilled in the art will readily understand that the value of M associated with the number of reception zones 202-n of the receiver component 200 may be different from the value N defining the number of emission zones 102-n of the emitter component 100.

Moreover, the micro-tubes 310-p may be designated by the reference 310 in the remainder of the description or in the figures, also by way of simplification.

A signal propagation micro-tube 310 may be characterized as an optical and/or electro-optical waveguide having two transverse ends and comprising a longitudinal internal medium 312 and a wall 314. The waveguide forming the micro-tube is designed to propagate the optical component (that is to say the one carrying optical information) of a signal through the medium 312, also called ‘propagation medium’ or ‘transmission medium’. The wall 314 of a micro-tube is designed to separate the propagation medium 312 of the micro-tube and the ambient medium 40 in which the device 10 is immersed.

The ambient medium 40 of the device 10 may also be a medium under vacuum, or a gaseous medium such as air or a neutral gas such as nitrogen or argon. In this case, the device 10 may be integrated into an enclosure designed to control the impact of the medium on the optical and/or mechanical stability of the communicating rays, that is to say interconnect pads between the emissive matrix and the receiving matrix, by controlling for example the pressure and temperature parameters in this enclosure. In some embodiments, the ambient medium 40 of the device 10 may also be a solid medium, or a hybrid medium such as a material known as an underfill material. Such a material may be epoxy adhesive, for example.

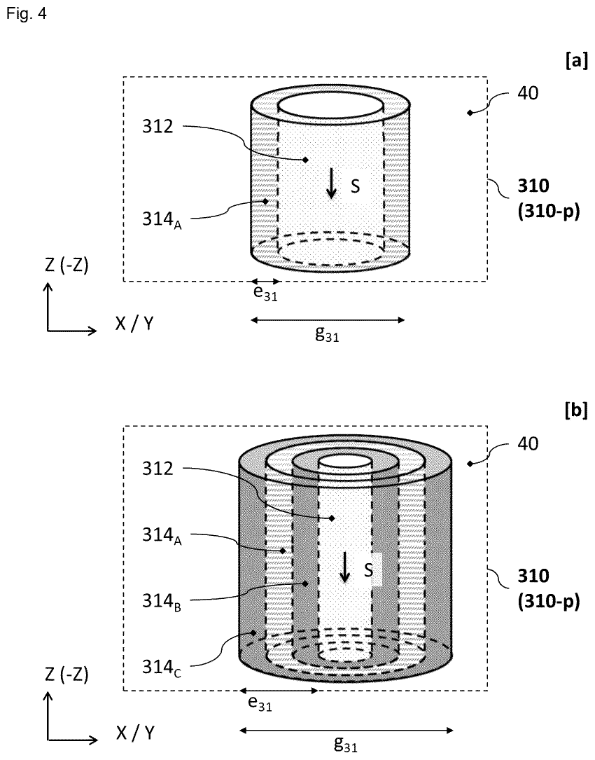

Diagrams 4[a] and 4[b] of FIG. 4 illustrate examples of micro-tubes 310, shown schematically and distinctly in the ambient medium 40, in a perspective view. Such a micro-tube 310 forming a waveguide may notably extend along an axis substantially parallel to the axis Z of the reference system (X, Y, Z) associated with the transmission device 10.

In some embodiments, the propagation medium 312 of a micro-tube 310 may correspond to a liquid body, vacuum, a gaseous medium such as air or a neutral gas such as nitrogen or argon, or a solid or hybrid material (or filler material, sealing material) such as polysilicon, an oxide or else a nitride. The composition of the propagation medium 312 may be determined based on at least certain characteristics of the signal to be transmitted.

In particular, the composition of the propagation medium 312 may be chosen depending on the difference in optical index between the propagation medium 312 and the wall 314, so as to optimize the propagation of the optical component (carrying optical information) of the signal to be transmitted, through the waveguide formed by the micro-tube 310, and notably via the transmission medium.

In some embodiments, the composition of the propagation medium 312 may be chosen depending on the composition of the ambient medium 40 of the device 10. In particular, the composition of the propagation medium 312 may be identical to the composition of the ambient medium 40.

In some embodiments, the propagation medium 312 may be a liquid medium, thereby allowing the device 10 to form a microlens for immersion scanner applications. For example and without limitation, the propagation medium 312 may be distilled water, deionized water and/or any liquid suitable for an internal lens function such that the propagation of the optical signal in this propagation medium 312 is suited to the requirement predefined by a designer of the transmission device 10.

The composition of the propagation medium 312 may also be defined based on the emission optical frequency band λ₁ₙ of the optical component of a signal S₁ₙ emitted by the emission zone 102-n. For example and without limitation, the composition of the propagation medium 312 may be chosen such that the propagation medium 312 is transparent (that is to say optically transparent) to the optical component of the signal S₁ₙ to be transmitted. In this case, the emission optical frequency band λ₁ₙ of the optical component of the signal S₁ₙ penetrating the medium 312 may be substantially equal (or equivalent) to the reception optical frequency band λ₂ₙ of the optical component of the signal S₂ₙ propagated through the propagation medium 312. This frequency band match between the emitted signal and the resulting signal at the output of the micro-tube 310 makes it possible to guarantee low attenuation, that is to say low loss, of the optical information caused by transmission in the interconnect component 300.

As an alternative, the composition of the propagation medium 312 may be chosen so that this medium has filtering and/or optical shifting functions, such that the emission and reception optical frequency bands λ₁ₙ and λ₂ₙ are different (that is to say mutually distinct). One example of a filtering function may be a filtering function applied depending on the optical index of the chosen composition of the propagation medium 312.

In one variant of the invention, the composition of the propagation medium 312 may have active or variable optical properties depending on modifications of the physical state of the device 10 or of the interconnect component 300. The composition of the propagation medium 312 may be chosen notably such that its optical index is able to be modified depending on changes in thermal and/or ambient conditions. For example and without limitation, these modifications may make it possible to achieve active tunability to the emission and/or reception optical frequency bands λ₁ₙ and/or λ₂ₙ, in response to a command to modify the temperature of the ambient medium 40.

Moreover, the composition of the propagation medium 312 may be a polarization-rotating transmission medium, or alternatively a polarization-maintaining transmission medium, such that the polarization of the optical component of the emitted signal S₁ₙ is substantially equal (or equivalent) to the polarization of the optical component of the received signal S₂ₙ. For example, such a polarization rotation may be generated (or obtained) depending on the optical index of the chosen composition of the propagation medium 312.

In some embodiments, the wall 314 of a micro-tube 310 may comprise a single thickness (or wall), denoted 314_{A}, as illustrated in diagram 4[a] of FIG. 4.

Advantageously, the wall 314 (or 314_{A}) of a micro-tube 310 may comprise a single metal or dielectric thickness. For example and without limitation, such a wall thickness in FIG. 4[a] may be composed of tungsten, having a low electrical conductivity, or of an oxide material.

According to some embodiments, the wall 314 of a micro-tube 310 may comprise multiple distinct thicknesses (or walls). In particular, such a wall 314 may comprise at least one dielectric thickness and at least one metal thickness. For example and without limitation, a wall 314 may comprise a central dielectric part 314_{A}, an inner metal part 314_{B} and/or an outer metal part 314_{C} that are concentric, each having the shape of a hollow cylinder (that is to say the bases of which are rings), with the same axis as the micro-tube 310, as shown in diagram 4[b] of FIG. 4. Each part 314_{A}, 314_{B} and 314_{C} has a given thickness (equal to the difference between the outside radius and the inside radius of the rings forming the base of each part). A metal part 314_{B} or 314_{C} of the wall 314 may be composed of aluminium or gold, for example. A metal part 314_{B} or 314_{C} of the wall 314 may also comprise a layer called a ‘bonding layer’ (not shown in the figures) placed against the dielectric part 314_{A} of the wall 314 of the waveguide, which may be composed of titanium or nitrided titanium, for example.

The internal and/or external metallization of the wall 314 of a micro-tube 310 may allow the electrical component of the signals, carrying electrical information, to be propagated (or transmitted) along the metallized wall of the waveguide.

The electrical component of a signal S₁ₙ coming from an emission zone 102-n may thus be transported from the emission component 102 to the reception component 202 through propagation in the interconnect component 300, and in particular a micro-tube 310. A micro-tube 310 may therefore have a dual function of transporting optical and electrical information. The electrical component of a signal S₁ₙ may also be designed to control certain functionalities of the micro-tube 310 over which it propagates. For example and without limitation, it is possible to implement active tunability of the emission and/or reception optical frequency bands λ₁ₙ and/or λ₂ₙ by modifying the optical index of the composition of the propagation medium 312-n of a micro-tube 310-n, in response to an electrical command coming from the electrical component of a signal S₁ₙ passing through the micro-tube.

The wall 314 of a micro-tube 310 may be characterized by an overall wall thickness e₃₁ (difference between the inside radius and the outside radius of the micro-tube 310 if the micro-tube has an annular cross section, for example), which may have a value of the order of a few micrometres to a few tens of micrometres. Such an overall thickness of the wall 314 may depend on the pitch of the array of micro-tubes 310-p in the transmission device 10. Advantageously, the metal parts 314B and/or 314C of a wall 314 may have a value of the order of a few tens of nanometres to a few hundred nanometres.

In some embodiments, a micro-tube 310 (and more particularly its wall 314) may be characterized by a given geometry (called a ‘transverse geometry’) in the plane (X, Y) and by a cross-sectional quantity g₃₁ relating to the cross section of the micro-tube 310 in the plane (X, Y). The shape of the transverse geometry of the micro-tube 310 and its quantity g₃₁ may be determined notably depending on the efficiency of the transmission of an optical and/or electro-optical signal through the waveguide formed by the micro-tube. Advantageously, the transverse guide geometry may be annular in the plane (X, Y), as shown in diagrams 4[a] and 4[b] of FIG. 4. Those skilled in the art will readily understand that a micro-tube 310 is not limited to such transverse geometry shapes and may have other transverse geometry shapes (that is to say the cross section of the micro-tube 310 may have other geometrical shapes) such as for example a square, rectangular, triangular, elliptical or trapezoidal shape, or any other suitable shape. In the case of an annular transverse geometry of the micro-tube 310, the cross-sectional quantity g₃₁ of a micro-tube may correspond to its internal diameter, for example, as shown in diagrams 4[a] and 4[b] of FIG. 4. The cross-sectional quantity g₃₁ may be of the order of a few micrometres to a few tens of micrometres. The cross-sectional quantity g₃₁ of the micro-tubes of the interconnect component 300 may be defined based on the distribution density of the optical sources of the emitter component 100.

The remainder of the description will be given mainly with reference to a micro-tube with an annular cross section by way of non-limiting example, for ease of understanding of the invention.

The shapes and the various dimensions associated with the micro-tubes 310 and the materials of which they are composed may be chosen so as to obtain optimum mechanical strength of the component 300. For example, the use of oxide material to generate the propagation medium 312 and/or the wall 314 of a micro-tube 310-p may make it possible to improve the mechanical connection between the emitter component 100 and the receiver component 200.

The interconnect component 300 may comprise a plurality of optical assemblies 50-n, each optical assembly 50-n comprising at least an emission zone 102, an associated micro-tube 310 and an associated reception zone 202 connected to the emission zone 102 by the micro-tube 310.

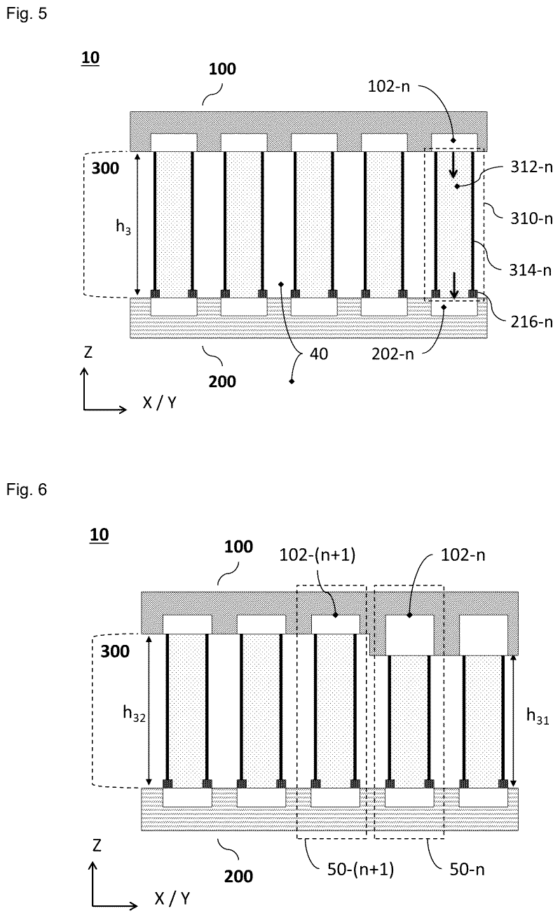

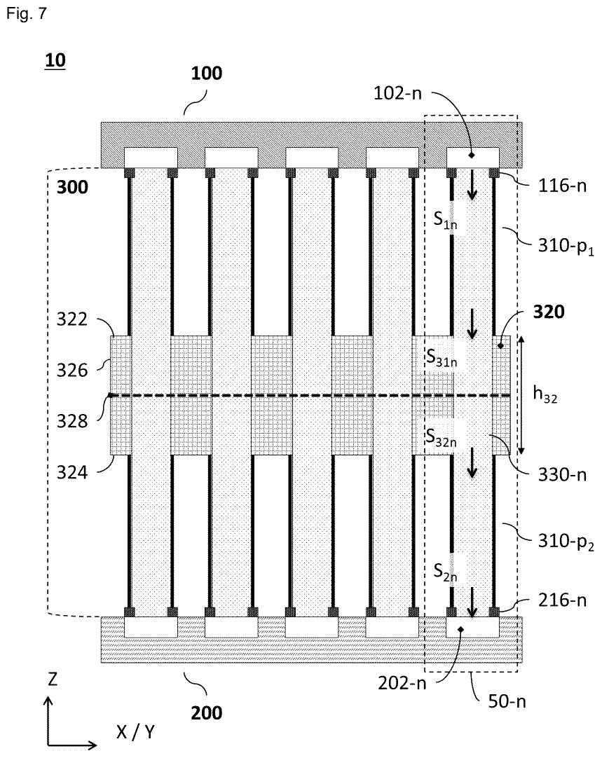

FIG. 5, FIG. 6 and FIG. 7 schematically show embodiments of an interconnect component 300 in a transmission device 10. The interconnect component 300 may comprise adjacent micro-tubes 310-p (or groups of micro-tubes) arranged in parallel with one another, extending along an axis substantially parallel to the axis Z.

It should be noted that a multi-thickness wall 314 formed of a dielectric part 314A composed of multiple layers of dielectrics with variable optical indices, or comprising at least one metallized part 314_{B} and/or 314_{C}, may advantageously allow the wall of the waveguide to be opacified. A wall 314 thickness said to be ‘opacifying’ makes it possible to increase the resulting difference in optical indices between the propagation medium 312 and the wall 314 of the waveguide. Such an increase results in an improvement in the propagation of the optical component of the signals in the propagation medium 312, that is to say along a micro-tube 310, by reducing or avoiding optical signal leakage. An opacified wall for a plurality of adjacent micro-tubes 310-p thus makes it possible to reduce parasitic communications between these various micro-tubes. The ‘crosstalk’ effect that may occur in conventional vertical connection devices is therefore significantly reduced by such opacification.

Moreover, it should be noted that a single-thickness wall 314 formed of a single dielectric part 314_{A}, generated from a metal thickness, may advantageously allow the wall of the waveguide to be opacified and therefore optical leakage phenomena (that is to say the ‘crosstalk’ effect) between the various optical channels formed by the set of juxtaposed micro-tubes to be avoided.

In the examples of FIGS. 5, 6 and 7, it is considered that the number M of reception zones 202-m is equal to the number N of emission zones 102-n, the index “m” of a reception zone 202-m then being substituted with the index “n” of an emission zone 102-n.

In some embodiments, the value of P may be equal to the value N corresponding to the number of emission zones 102-n of the emitter component 100 (which is itself equal to the value M of the number of reception zones of the receiver component 200), as shown in FIGS. 5, 6 and 7. In this case, the index “p” of a micro-tube 310-p is assimilated to the index “n” of the associated emission zones 102-n (and therefore to the index “m” of the reception zones 202-m), for the sake of simplification.

In particular, FIG. 5 schematically shows an interconnect component 300 comprising a plurality N (equal to P) of micro-tubes 310-n, according to some embodiments of the invention, each micro-tube 310-n being able to be configured to directly transmit the n^{th} signal S₁ₙ coming from an emission zone 102-n of the emitter component 100 to the receiver component 200, an n^{th} resultant signal S₂ₙ then being received by the reception zone 202-n. Each reception zone 202-n may thus be connected to a corresponding emission zone 102-n via an associated micro-tube 310-n. The length of the interconnect component 300 may then correspond substantially to the height h₃ of the micro-tubes 310-n, and may be of the order of a few micrometres to a few tens of micrometres.

A micro-tube 310-n of the interconnect component 300 may thus extend longitudinally between the emitter component 100 and the receiver component 200 in order to optically couple the emission zone 102-n associated with the micro-tube to the corresponding reception zone 202-n.

The arrangement of the micro-tubes 310-n may have a defined configuration with respect to the arrangement of the emission zones 102-n and the reception zones 202-n. For example, the arrangement of the micro-tubes 310-n may have a regular matrix configuration in the form of an array of micro-tubes. As an alternative, the arrangement of the micro-tubes 310-n may be defined with an irregular distribution of the micro-tubes. For example and without limitation, an irregular distribution of the plurality of micro-tubes may correspond to an interconnect component 300 comprising at least a first set of micro-tubes, defined with a first micro-tube spacing, and a second set of micro-tubes, defined with a second micro-tube spacing.

Advantageously, the arrangement of the micro-tubes 310-n may be determined depending on the arrangement constraints of the emission zones 102-n and/or of the reception zones 202-n.

The emission, reception and transverse geometries of each optical assembly 50-n of the transmission device 10 may advantageously be centred on one and the same axis, parallel to the axis Z.

In the embodiments in which the plurality of emission zones comprise various sets of hybrid sources, the emission component 102 may comprise an emission face 104, comprising various distinct level cross sections, as illustrated in FIG. 6. In particular, the emission component 102 may comprise:
a first set, corresponding, for example and without limitation, to sources coming from a CMOS chip comprising the reference emission zone 102-n shown in FIG. 6, and
a second set of other emissive elements comprising the reference emission zone 102-(n+1) shown in FIG. 6.

The sources of the first set may each have a first size, and the emissive elements of the second set may each have a second size, such that the resulting thickness of the emission component 102 (between the face 104 and the face 106) may be substantially variable from one set to another (that is to say from one emission zone to another). A thickness variable may be equal to at least two distinct values defined by the first and second sizes of the emission zones, respectively.

Those skilled in the art will readily understand that the reception component 202 may similarly comprise various sets of reception zones such that the thickness of the reception component 202 (between the reception face 204 and the face 206) may be substantially variable from one set to another (that is to say from one reception zone to another), according to one embodiment not shown in the figures.

Advantageously, the micro-tubes of the interconnect component 300 may then have various heights between the various emission and reception zones of the transmission device 10. In particular, the interconnect component 300 may comprise a first set of micro-tubes and a second set of micro-tubes, such that the height of the micro-tubes (between the emission face 104 and the reception face 204) may be substantially variable from one set to another. For example, the height of the micro-tubes of the first set of micro-tubes may be equal to a first value and the height of the micro-tubes of the second set of micro-tubes may be equal to a second value distinct from the first value. For example and without limitation, as illustrated in FIG. 6, the device 10 may comprise at least a first optical assembly 50-n and a second optical assembly 50-(n+1), and the micro-tube 310-n associated with the first optical assembly 50-n may be characterized by a height h₃₁ with a value less than the height h₃₂ of the micro-tube 310-(n+1) associated with the second optical assembly 50-(n+1).

The variability in heights of the micro-tubes of the interconnect component 300 makes it possible, during the fabrication of these micro-tubes, to compensate for the variabilities in thicknesses or levels of the hybrid emission and/or reception components 100 and/or 200. Such variability in heights of the micro-tubes also makes it possible to compensate for simple planarity defects with the emission and/or reception components 100 and/or 200 composed of the same elements, or else hybrid components.

In some embodiments, an optical assembly 50-n may comprise a coupling element 116-n associated with the emission zone 102-n of the optical assembly 50-n and configured to couple the emitter component 100 to the interconnect component 300. An ‘emission’ coupling element 116-n may be arranged on the emission face 104 in the emission zone 102-n, as illustrated in FIG. 7.

In some embodiments, an optical assembly 50-n may comprise a coupling element 216-n associated with the reception zone 202-n of the optical assembly 50-n and configured to couple the receiver component 200 to the interconnect component 300. A ‘reception’ coupling element 216-n may then be positioned on the reception face 204 in the reception zone 202-n, as illustrated in FIGS. 5, 6 and 7.

Advantageously, an emission and/or reception coupling element 116-n or 216-n has a cross section that may have any suitable geometrical shape, in the plane (X, Y), and be characterized by a quantity gₙ relating to a dimension parameter of the geometrical shape of the cross section of the coupling element in the plane (X, Y). In particular, the geometrical shape and the quantity gₙ of a coupling element 116-n or 216-n may be chosen depending on the shape of the cross section of the associated micro-tube 310-n and the dimensions of this cross section. The geometrical shape of the cross section of a coupling element 116-n and/or 216-n, in the plane (X, Y), may be the same as the geometrical shape (that is to say transverse geometry) of the cross section of the associated micro-tube 310-n, and may be centred on the same axis as the micro-tube 310-n. A coupling element 116-n and/or 216-n may be arranged between the associated emission zone 102-n and/or the associated reception zone 202-n, respectively, on the one hand, and the upper edge and/or the lower edge of the wall 314 of the associated micro-tube 310-n, respectively, at its upper and/or lower end, respectively.

If a micro-tube 310-n has a cylindrical shape, a coupling element 116-n and/or 216-n may have an annular (that is to say ring-shaped) cross section in the plane (X, Y) adapted to the annular shape of the cross section of the wall 314 of the micro-tube in order to be able to be held between the associated emission zone 102-n and/or the associated reception zone 202-n, respectively, on the one hand, and the upper edge and/or the lower edge of the wall 314, respectively, on the other hand. In such embodiments, an emission coupling element 116-n and/or 216-n may be centred around the centre of the emission zone 102-n and/or of the reception zone 202-n, respectively, as shown for example in diagrams 2[b] of FIGS. 2 and 3[b] of FIG. 3. A coupling element 116-n or 216-n may have a cross section of any geometrical shape, in a manner adapted to the shape of the cross section of the micro-tube 310, such as for example a square, rectangular, triangular, elliptical, trapezoidal, hexagonal, polygonal, etc. shape. A coupling element 116-n or 216-n may have a size of the order of a few micrometres to a few hundred micrometres.

The arrangement of the various optical assemblies 50-n in relation to one another may have any suitable configuration. The various elements (or objects) in one and the same optical assembly 50-n (which may comprise the emission zone 102-n, the reception zone 202-n, the micro-tube 310-n, and the one or more coupling elements 116-n and 216-n) may be centred around the same axis (axis parallel to the axis Z), this axis possibly passing through the centre of the emission zone 102-n and of the reception zone 202-n.

In the example of FIGS. 5, 6 and 7, the transmission device 10 comprises multiple optical assemblies 50-n (5 optical assemblies in these examples), each optical assembly comprising an emission zone 102-n that may notably be coupled (or connected) to a micro-tube 310-n by an emission coupling element 116-n, and a reception zone 202-n coupled (or connected) to the micro-tube 310-n by a reception coupling element 216-n. A coupling element 116-n and/or 216-n (also called a ‘receiving pad’) may, for example, be composed of a malleable metal material.

As used here, the expression ‘malleable’ (or ductile) refers to the ability of a material to withstand stresses without breaking, in particular compressive stresses. For example and without limitation, a coupling element may be formed at least partly of gold, indium, aluminium or the like.

A coupling element 116-n and/or 216-n makes it possible to transmit, in the transmission device 10, the optical and/or electro-optical signal in each optical assembly 50-n, at the junction between an emission zone 102-n and the associated micro-tube 310-n, and/or between a reception zone 202-n and the associated micro-tube 310-n, respectively. The coupling elements 116-n and 216-n thus enable optical “sealing”, and advantageously electrical contact (or electrical connection) between the junction elements of the components of the device 10. The coupling elements 116-n and 216-n are thus electrical coupling and optical sealing elements. The coupling elements 116-n and 216-n are also mechanical coupling elements, the insertion of each micro-tube into at least one receiving pad making it possible to ensure mechanical strength between the various components of the device 10.

In some embodiments, the value of P corresponding to the number of micro-tubes 310-p may be different from the number N of emission zones 102-n of the emitter component 100 (M being equal to N). In such embodiments, each optical assembly 50-n may comprise a plurality of micro-tubes 310-pₖ (the index “k” being an integer between 1 and K, K being the number of micro-tubes 310 per optical assembly 50-n) having the same axis and cross section, arranged between the emission zone 102-n and the reception zone 202-n of the optical assembly 50-n.

In some embodiments, an interconnect component 300 may comprise a number of micro-tubes equal to a multiple of N, according to some embodiments of the invention. The interconnect component 300 may comprise a plurality of micro-tubes subdivided (or intersected) by at least one intermediate substrate 320. In particular, an intermediate substrate 320 of the component 300 may be designed to delimit two sets of micro-tubes, on either side of an intermediate substrate. The total number P of micro-tubes 310 of the transmission device may for example be equal to twice N, as illustrated in FIG. 7. In the case of FIG. 7, each optical assembly 50-n comprises two micro-tubes 310-p₁ and 310-p₂ (K=2) separated by an intermediate substrate 320 passing through the interconnect component 300, and each optical assembly comprises the same number of micro-tubes 310 (K=2).

The intermediate substrate 320 may have a generally planar structure, extending in the plane (X, Y). The intermediate substrate 320 of the interconnect component 300 may comprise a first face 322 (also called an ‘input face’) facing the face 104 of the emitter component, and a second face 324 (also called an ‘output face’) opposite the first face 322 and facing the face 204 of the receiver component 200. The first and second faces 322 and 324 of the intermediate substrate 320 may be substantially parallel to one another, defined in the plane (X, Y), and may be connected by a lateral edge 326 (in the plane (Y, Z)), as shown in FIG. 7. The intermediate substrate 320 may have any suitable geometrical shape and dimension.

Advantageously, an intermediate substrate 320 of the interconnect component 300 may be designed to transmit (optical and/or electro-optical) signals between the micro-tubes 310 of one and the same optical assembly 50-n (in the case of FIG. 7, between the two micro-tubes 310-p₁ and 310-p₂ of the pair of micro-tubes of each optical assembly 50-n). The micro-tubes 310 of one and the same optical assembly 50-n (micro-tubes 310-p₁ and 310-p₂ in the case of FIG. 7) extend along one and the same axis, substantially parallel to the axis Z. As shown in FIG. 7, the first micro-tube 310-p₁ is connected firstly to the emission zone 102-n and secondly to the input face 322 of the intermediate substrate 320, which is capable of receiving a signal to be propagated in the intermediate substrate 320. The second micro-tube 310-p₂ is connected firstly to the output face 324 of the intermediate substrate, via which the signal propagated in the intermediate substrate 320 leaves, and secondly to the reception zone 202-n of the photonic device 10.

The intermediate substrate 320 may comprise one or more micro-vias (or micro-holes) for propagating a signal, according to some embodiments of the invention. In particular, the intermediate substrate 320 may comprise a plurality of N micro-vias 330-n (also called ‘interconnect micro-vias’), each micro-via 330-n being associated with an optical assembly 50-n and being configured to transmit the n^{th} signal S₃₁ₙ coming from the first micro-tube 310-p₁ of the optical assembly 50-n to the second micro-tube 310-p₂ of the optical assembly 50-n, in the form of an nth signal S₃₂ₙ resulting from passing through the intermediate substrate 320.

The arrangement and configuration of the micro-vias 330-n may be adapted to the arrangement and configuration of the various optical assemblies 50-n.

Each micro-via 330-n for propagating signals in an intermediate substrate 320 may be characterized in the form of an optical and/or electro-optical waveguide, comprising a longitudinal medium 332-n and a wall extending along an axis substantially parallel to the axis Z of the reference system (X, Y, Z) associated with the transmission device 10. The waveguide characterizing a micro-via 330-n is designed to propagate the optical component (that is to say the one carrying optical information) of a signal through the propagation medium 332-n. The wall of a micro-via 330-n may then be formed by the separation between the propagation medium 332-n and the intermediate substrate 320.

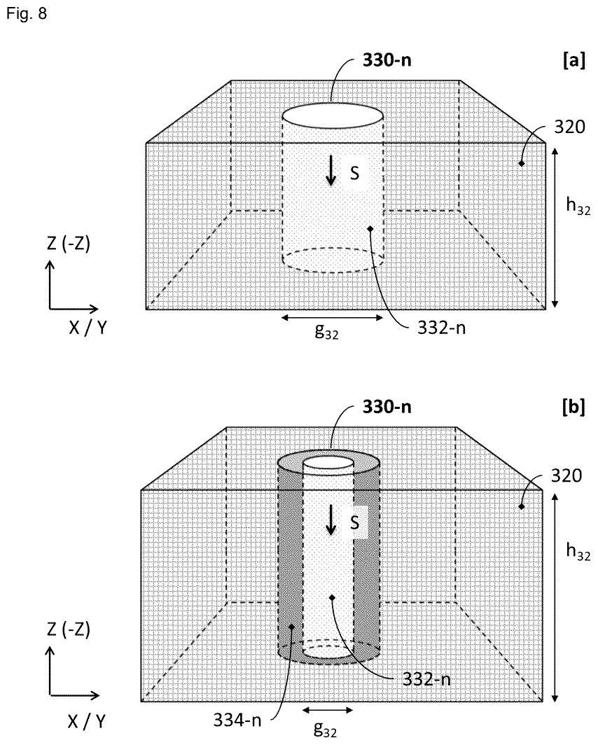

Diagrams 8[a] and 8[b] of FIG. 8 schematically illustrate a micro-via 330-n arranged in an intermediate substrate 320 in a perspective view.

The propagation medium 332-n for propagating the signal in a micro-via 330-n may correspond to vacuum, a liquid body, a gaseous medium such as air or a neutral gas such as nitrogen or argon, or to a solid material (or filler material) such as polysilicon, an oxide, a polymer or else a nitride. Advantageously, the propagation medium 332-n for propagating the signal in a micro-via 330-n may be substantially identical to the propagation medium 312 of the one or more micro-tubes 310 of the same optical assembly 50-n.

In some embodiments, a micro-via 330-n may comprise a metal surface 334-n, with a given thickness, on the periphery of the waveguide (that is to say the wall), as shown in diagram 8[b] of FIG. 8. The metal surface (or wall) 334-n of the micro-via 330-n may have the shape of a hollow cylinder. The metal surface 334-n of the micro-via 330-n may for example be composed of aluminium, copper or gold and may have a thickness of the order of a few tens of nanometres to a few hundred nanometres.

In some embodiments, the intermediate substrate 320 may be formed from one or more semiconductor materials such as, for example and without limitation, from at least part of a wafer made of silicon, germanium, gallium arsenide (AsGa), indium phosphide (InP), crystalline silicon, glass, sapphire, ceramic materials or the like. The intermediate substrate 320 may be composed of any type of planar support conforming to microelectronics criteria, such as criteria according to the SEMI standards for example. The height h₃₂ of the micro-vias 320-n (along the axis Z) is then equal to the height of the intermediate substrate 320 (along the axis Z). The height h₃₂ of a micro-via 320-n may be for example of the order of a few tens of micrometres to a few millimetres.

In some embodiments, the intermediate substrate 320 may be formed of multiple intermediate sub-substrates separated in pairs by an interface 328 (an interface 328 is thus interposed between two intermediate sub-substrates), as shown in FIG. 7. An interface 328 may comprise for example a mounting layer composed of an adhesive optically transparent to the optical component of the signals to be propagated along the micro-vias 320-n. This interface 328 may also be formed by polymer bonding, for example using an epoxy, polyimide, acrylic or silicone adhesive. Epoxy adhesives may be insulating, conductive, thermally conductive (for favourable heat dissipation) or electrically conductive (for promoting both heat dissipation and electrical connection between two assembled substrates). Moreover, the intermediate substrate 320 may be formed by metal brazing (or metal bonding), that is to say via an assembly of sub-substrates brazed using fusible alloys such as those derived from the tin or indium family. The intermediate substrate 320 may also be formed from an assembly of sub-substrates using hybrid bonding, that is to say via direct bonding without an intermediate bonding layer between two mixed substrate surfaces comprising dielectric parts (for example oxide or SiO₂) and metal parts (for example copper), by placing the metal parts of the two surfaces facing one another so as to make an electrical connection between the assembled metal parts. Metal or hybrid bonding makes it possible to transmit the electrical component of the signals to be propagated along the micro-vias 320-n (that is to say carry electrical information). In this case, the bonding interface is of substantially negligible thickness compared to the height h₃₂ of the micro-vias 320-n.

The metallization 334-n of the wall of a micro-via 330-n allows the electrical component (the one carrying electrical information) of the signal to be propagated (or transmitted) along the metallized wall of the micro-via 330-n, through the intermediate substrate 320 of the interconnect component 300. Moreover, such a metallization may also allow an increase in the difference in refractive indices between the transmission medium 332-n and the material of the intermediate substrate 320 so as to improve the propagation of the optical component of the signal through the transmission medium.

A micro-via 330-n may be characterized by a cross section having a given geometrical shape in the plane (X, Y) and by a quantity denoted g₃₂ₙ relating to a dimension parameter of the cross section of the micro-via 330-n. Advantageously, the geometrical shape of the cross section of the micro-via 330-n may be generally circular in the plane (X, Y), as shown in diagrams 8[a] and 8[b] of FIG. 8. In this case, the characteristic quantity g₃₂ₙ of a micro-via may correspond to the diameter or radius of its cross section, and may be of the order of a few micrometres to a few hundred micrometres. In some embodiments, the characteristic quantity g₃₂ₙ of a micro-via 330-n may be equal to the characteristic quantity g₃₁ of the one or more micro-tubes 310 of the same optical assembly 50-n. As an alternative, the characteristic quantity g₃₂ₙ may be different from the characteristic quantity g₃₁ in one and the same optical assembly 50-n. For example and without limitation, a characteristic quantity g₃₂ₙ of a micro-via 330-n greater than a characteristic quantity g₃₁ of a micro-tube 310-n positioned upstream of the micro-via 330-n makes it possible to optically fan out the input beam of the micro-via 330-n, and in particular to widen the beam size of the signal S₃₁ₙ. A characteristic quantity g₃₂ₙ of a micro-via 330-ₙ less than a characteristic quantity g₃₁ of a micro-tube 310-n positioned upstream of the micro-via 330-n makes it possible to optically focus the input beam of the micro-via 330-n, and notably to reduce the beam size of the signal S₃₁ₙ.

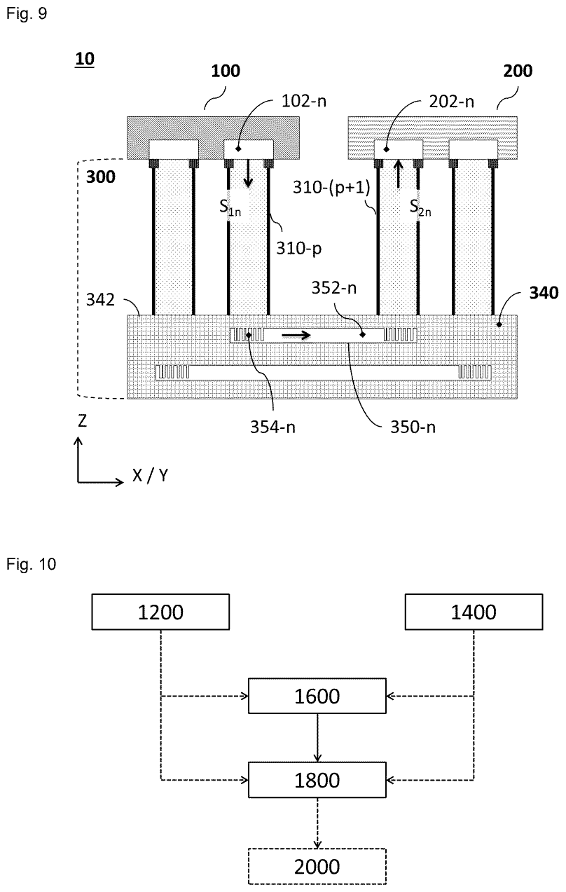

In some embodiments, the interconnect component 300 may alternatively comprise a plurality of micro-tubes subdivided (or intersected) by at least one transfer unit 340, each unit delimiting two sets of micro-tubes on either side of the transfer unit 340, as illustrated in FIG. 9.

In such embodiments using a transfer unit 340, each optical assembly 50-n comprises a plurality of substantially parallel micro-tubes 310-pₖ (“k” being between 1 and K, K being the number of micro-tubes 310 per optical assembly 50-n) having the same cross section but that are not collinear, arranged between the emission zone 102-n and the reception zone 202-n of the optical assembly 50-n.

In the example of FIG. 9, each optical assembly 50-n comprises two micro-tubes 310-p₁ and 310-p₂ (K=2) separated by a transfer unit 340 passing through the interconnect component 300, and each optical assembly comprises the same number of micro-tubes 310 (K=2). Thus, in the example of FIG. 9, the number P of micro-tubes is equal to twice N. The two micro-tubes 310-p₁ and 310-p₂ of one and the same optical assembly may advantageously have the same cross section but may be centred on distinct and mutually parallel axes (parallel to the axis Z). In the example of FIG. 9, the axis of the second micro-tube 310-p₂ of an optical assembly 50-n is offset along the axis X from the axis of the first micro-tube 310-p₁ of the same optical assembly.

Similarly to an intermediate substrate 320, a transfer unit 340 of the interconnect component 300 may be designed to transmit (optical and/or electro-optical) signals between distinct micro-tubes 310 of one and the same optical assembly 50-n.

A transfer unit 340 may comprise a plurality of communication channels 350-n corresponding to a planar or quasi-planar array of optical and/or electro-optical waveguides extending for example substantially in the plane (X, Y). A transfer unit 340 may be for example an integrated photonic interposer or a photonic integrated component (PIC), corresponding to a substrate comprising a plurality of optical elements, one or more of these elements being associated with a photonic function. Each communication assembly 50-n is associated with a communication channel 350-n of the transfer unit.

In some embodiments, a communication channel 350-n for propagating signals in the transfer unit 340 may be characterized by an optical waveguide 352-n and have two ends 354-n. One end 354-n of a communication channel 350-n may be, for example and without limitation, an integrated lens, or else a signal transmission grating between the waveguide 352-n characterizing the communication channel and a micro-tube 310-p₁ or 310-p₂ of the associated optical assembly 50-n. Such transmission gratings 354-n may be Bragg gratings for example, designed to modify the propagation direction of the optical component of a signal, notably by transforming the propagation direction along an axis substantially parallel to the axis Z into a propagation direction along an axis in the plane (X, Y).

In the example of FIG. 9, at its ends, the first micro-tube 310-p₁ is connected firstly to the emission zone 102-n (on the emission face 104) and connected secondly to the face 342 of the transfer unit 340, that is to say optically connected opposite one end 354-n of a communication channel 350-n. At its ends, the second micro-tube 310-p₂ is connected firstly to the face 342 of the transfer unit 340, that is to say optically connected opposite another end 354-n of a communication channel 350-n, and connected secondly to the reception zone 202-n (reception face 204) of the transmission device 10.

A micro-tube 310 of an optical assembly 50-n of the interconnect component 300 may thus extend longitudinally between the emitter component 100 and the transfer unit 340, and another micro-tube of the same optical assembly 50-n of the interconnect component 300 may extend longitudinally between the transfer unit 340 and the receiver component 200 in order to optically couple the emission zone 102-n to the corresponding reception zone 202-m of the optical assembly 50-n.

In some embodiments, a photonic interposer may be equipped with micro-vias (TSV or TGV) in order to meet specific requirements for complex transmissions between emitter and receiver components, such as in the case of transmissions of polarization electrical signals or optical signals.

In other embodiments, an interconnect component 300 may comprise a plurality of micro-tubes 310, at least one intermediate substrate 320 and/or at least one transfer unit 340. For example and without limitation, the interconnect component 300 may comprise at least a first set of micro-tubes 310 extending longitudinally between the emitter component 100 and the transfer unit 340, and at least two other sets of micro-tubes 310 extending respectively:
between the transfer unit 340 and the intermediate substrate 320, and
between the intermediate substrate 320 and the receiver component 200.

In the embodiments in which the interconnect component 300 comprises at least one micro-tube 310 and a transfer unit 340, the interconnect component 300 may also comprise a connection substrate. The connection substrate (not shown in the figures) may have characteristics similar to the intermediate substrate 320 described above and may comprise in particular at least one micro-via. The connection substrate may be arranged between the transfer unit 340 and the receiver component 200. For example and without limitation, each optical assembly 50-n of the interconnect component 300 may comprise at least one micro-tube 310 extending longitudinally (along the axis Z) between the emitter component 100 and the receiver component 200, via the transfer unit 340 and the connection substrate (placed between the transfer unit 340 and the receiver component 200). One end of the micro-via of the connection substrate may be optically connected to one end of a communication channel of the transfer unit 340 (connected to the face 343), whereas the other end of the micro-via of the connection substrate may be connected to a reception zone 202-n (reception face 204) of the transmission device 10. In other words, the interconnect component 300 may comprise at least one micro-via extending longitudinally between the transfer unit 340 and the receiver component 200.

In some embodiments, the number N of emission zones of the emitter component 100 may be different from the value of the number M of reception zones of the receiver component 200 (embodiment not shown in the figures). For example, an intermediate substrate 320 or a transfer unit 340 of the interconnect component 300 may comprise one or more auxiliary optical elements for:
dividing an optical path (or channel) into two or more optical paths, or
combining two or more optical paths into a single optical path.

Such auxiliary optical elements may be passive or active and, in this case, may supply power and/or carry out driving based on a power supply signal (that is to say an electric current) coming from an emission zone 102-n. An auxiliary optical element may correspond for example to an optical selector or an optical recombiner.

The transmission device 10 may be fabricated using any technologies and tools suitable for forming the elements making up the transmission device 10, the dimensions of which are on the micrometric and nanometric scale. The technologies used to fabricate these structures may be integrated circuit production technologies. In particular, the transmission device 10 may be fabricated using a process comprising a design phase and a phase of physically fabricating the transmission device 10.

The phase of designing the transmission device 10 may comprise a set of steps for responding to an analysis of electro-optical simulations and/or the requirement of the system using the transmission device 10 (which may be for example a transceiver system or an optical signal conversion system). The phase of designing the transmission device 10 may for example be computer-implemented. For example, the phase of designing the transmission device 10 may be implemented via software for simulating and optimizing optical signals travelling through waveguides and photonic interposers.

The phase of physically fabricating the transmission device 10 takes into account the results from the design phase implemented beforehand.

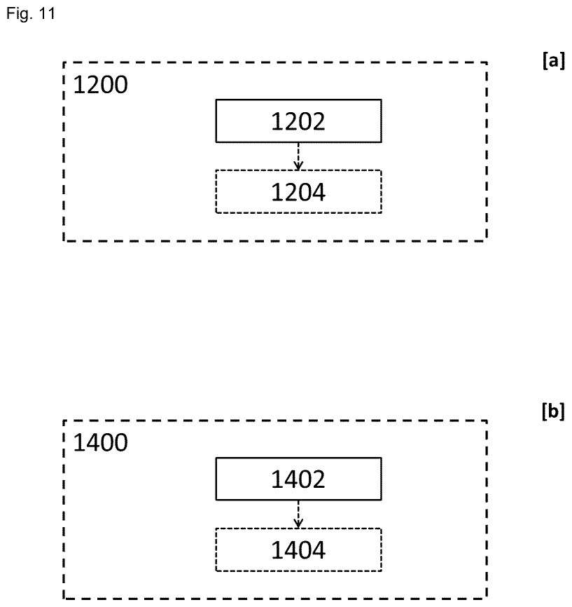

FIG. 10 is a flowchart showing steps of the phase of fabricating the transmission device 10, according to some embodiments of the invention.

In steps 1200 and 1400, the emitter component 100 and the receiver component are fabricated (or prepared or assembled) separately.

In step 1600, the interconnect component 300 is fabricated so as to comprise at least one micro-tube 310.

In step 1800, the emitter component 100 and the receiver component 200 are assembled, via the interconnect component 300, thereby providing an initial transmission device 10.

In particular, the assembly step 1800 for forming the transmission device 10 may be carried out in a vacuum enclosure or under a controlled atmosphere, such that the ambient medium 40 of the device 10 is a medium under vacuum, or a gaseous medium such as air or a neutral gas such as nitrogen or argon.

In step 2000, the fabricated transmission device 10 may then be inserted into a transceiver system or into an optical signal conversion system, depending on the application of the invention. In particular, step 2000 may comprise a sub-step of cutting at least part of the initial device in order to obtain an application device comprising a desired number of optical assemblies 50-n.

Diagrams 11[a] and 11[b] of FIG. 11 are flowcharts showing examples of sub-steps of steps 1200 and 1400 of preparing (or fabricating or assembling) the emitter component 100 and the receiver component 200, respectively, in the phase of physically fabricating the transmission device 10, according to some embodiments of the invention.

Preparing the emitter component 100 in the physical fabrication phase may comprise an initial sub-step 1202 of preparing, assembling or providing an emissive substrate equipped with a multitude of integrated or remote light sources (that is to say emission zones).

Similarly, preparing a receiver component 200 in the physical fabrication phase may comprise an initial sub-step 1402 of preparing, assembling or providing a receiver substrate equipped with a multitude of integrated or remote light acquisition units (that is to say reception zones).

For example and without limitation, such initial sub-steps 1202 and 1402 may be carried out using suitable packaging technologies, such as pick-and-place, mass transfer, lamination and/or direct bonding processes, such as ‘chip-to-chip’, ‘chip-to-wafer’ or ‘wafer-to-wafer’ bonding.

In some embodiments, the physical fabrication phase may comprise a sub-step 1204 of assembling the emitter component 100 and/or a sub-step 1404 of assembling the receiver component 200, consisting in depositing coupling elements, respectively 116-n and 216-n. These coupling elements may be deposited on the emission face 104 of the emitter component 100 in the extension of each of the emission zones 102-n, or on the reception face 204 of the receiver component 200 in the extension of each of the reception zones 202-n.

Advantageously, as shown in the diagrams of FIGS. 2 and 3, the coupling elements 116-n and 216-n may be doughnut circular metallizations with a configuration analogous to the micro-tubes 310 of the interconnect component 300. The size and thickness of the coupling elements, following sub-steps 1204 and 1404, corresponding to the quantities hᵢ and eᵢ, may then be between a few nanometres and several micrometres. For example, the size and thickness may be equal to 2 μm and 0.2 μm, respectively. The coupling elements 116-n and 216-n may correspond to receiving pads for the associated micro-tubes 310. These metallizations may consist of gold, indium, aluminium and in general any sufficiently electrically conductive material suitable for deposition and etching techniques used in microelectronics.

In some embodiments, the size hi and the thickness eᵢ of the coupling elements 116-n and 216-n may be defined depending on the cross-sectional quantity g₃₁ of an associated micro-tube 310-n and/or on the separation distance d_{(n, n+1)} between the various emission zones, between the various reception zones and/or between the various micro-tubes to be fabricated.

Moreover, the size hi and the thickness eᵢ of a coupling element may also be defined depending on the insertion depth of the associated micro-tube 310-n so as to achieve a target safety value that makes it possible to guarantee optical sealing and “zone/micro-tube” electrical contact, that is to say electrical contact between a zone in question, 102-n or 202-n, and an associated micro-tube 310-n.

In the embodiments using a sub-step 1204, the associated micro-tubes 310 may be prepared separately from the assembly of the emitter component 100. Similarly, in the embodiments using a sub-step 1402, the associated micro-tubes 310 may be prepared separately from the assembly of the receiver component 200.

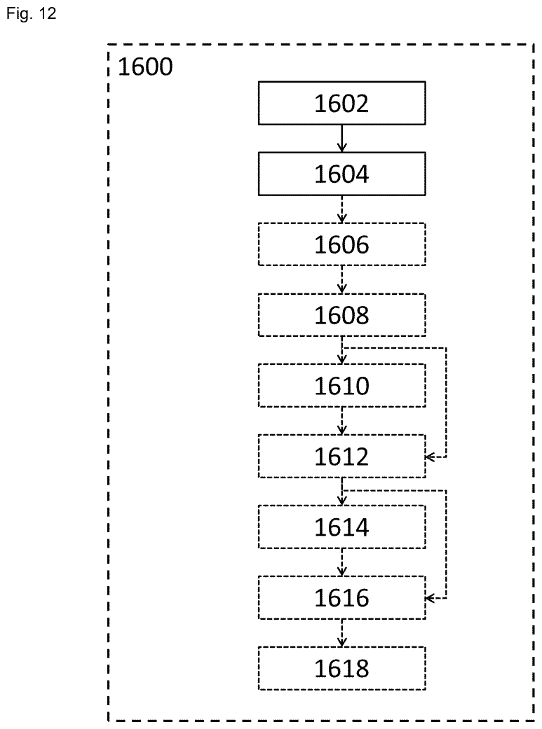

FIG. 12 is a flowchart showing the step 1600 of assembling the interconnect component 300, in the phase of physically fabricating the transmission device 10, according to some embodiments of the invention.

Assembling the interconnect component 300 in the physical fabrication phase may comprise an initial sub-step 1602 of providing one or more support substrates.

In some embodiments of the process for fabricating the transmission device 10, a support substrate may be the emitter component 100 (as illustrated in FIG. 5) or the receiver component 200 previously assembled in steps 1200 and 1400. A support substrate for preparing the interconnect component 300 may also be an integrated photonic interposer, for example (as illustrated in FIG. 9).

According to some embodiments, a support substrate may be any semiconductor material, such as for example all or part of a wafer made of silicon, germanium, gallium arsenide (AsGa), indium phosphide (InP), crystalline silicon or the like. A support substrate may also be formed from any non-semiconductor material, such as for example glass, sapphire or ceramics. Such a support substrate may have a substantially planar structure, and generally extend in the plane (X, Y). For example and without limitation, a wafer may typically have a thickness of 525 μm and a diameter of 100 mm. The support substrate may have a thickness of 725 μm and a diameter of 200 mm, or a thickness of 775 μm and a diameter of 300 mm.

It should be noted that, in initial sub-step 1602, a support substrate formed by a wafer may be characterized by a first face (also called a ‘support face’) and a second face (also called a ‘back face’) opposite the first face. The first and second faces may be substantially parallel to one another and defined in the plane (X, Y). The support substrate may have geometrical shapes and dimensions that are variable in the plane (X, Y). In sub-step 1604 of assembling the interconnect component 300, for each support substrate provided, micro-tubes 310 are fabricated on a specific face of the support substrate. For example and without limitation, the micro-tubes may be manufactured in an array configuration using a succession of photolithography, deposition and/or etching steps.

The use of suitable microelectronics technologies, such as very large scale integration (VLSI) techniques, makes it possible to guarantee the formation of up to several million micro-tubes in parallel, over an area of a few square centimetres. The chosen level of densification of the micro-tubes is limited a priori only by the minimum separation distance between emission and/or reception zones, and is therefore limited only by the technical type and miniaturization of the sources and receivers. A high density of micro-tubes makes it possible to obtain optical signal transmission also at a high density.

In the embodiments in which a support substrate is the emitter component 100, each micro-tube may be produced on the emission face 104 opposite an associated emission zone 102-n. Similarly, in the embodiments in which a support substrate is the receiver component 200, each micro-tube may be produced on the reception face 204 opposite an associated reception zone 202-n. In these specific cases, as a result of sub-step 1604, at least part of the interconnect component 300 may be connected directly to the emitter component 100 or to the receiver component 200, respectively.

In the embodiments in which a support substrate is a wafer, the micro-tubes may be produced on the support face of the substrate. Furthermore, preparing the interconnect component 300 may also comprise a sub-step 1606 of thinning at least one support wafer, notably by polishing the back face of the substrate, using known processes associated with microelectronic fabrication. In this case, the resulting thickness of a support substrate after the thinning sub-step 1606 may be less than or equal to 100 μm, for example.

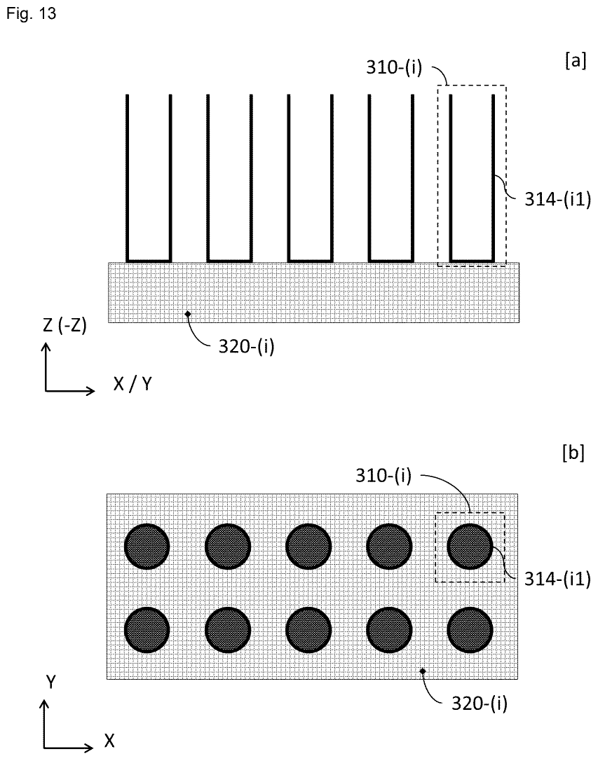

Diagrams 13[a] and 13[b] of FIG. 13 show, in the plane (X, Z) and the plane (X, Y), respectively, at least part of the interconnect component 300 in the process of being fabricated following sub-step 1604 or sub-step 1606, according to some embodiments of the invention. In particular, diagrams 13[a] and 13[b] show a support substrate, designated by the reference 320-(i), carrying micro-tubes 310-(i) in the process of being fabricated (or intermediate micro-tubes) distributed in a matrix configuration. Each micro-tube 310-(i) may be formed by a wall denoted 314-(i1) resulting from the fabrication sub-step 1604. A micro-tube wall 314-(i1) may consist of a dielectric material part, corresponding notably to the layer 314A of the wall 314 of a micro-tube 310-p of a fabricated interconnect component 300.

According to some embodiments, assembling the interconnect component 300 may comprise an initial sub-step 1608 of injecting (or depositing), between the micro-tubes of the set of micro-tubes 310 of the interconnect component 300, a sub-coating material (such as epoxy, polyimide, or more generally a polymer resin). This sub-coating material may be deposited by capillary action, for example. Its role is to protect the assembly and make it more reliable.

According to some embodiments, preparing at least part of the interconnect component 300 may comprise a sub-step 1610 of depositing metal layers locally over all or some of the micro-tubes fabricated on a support substrate.

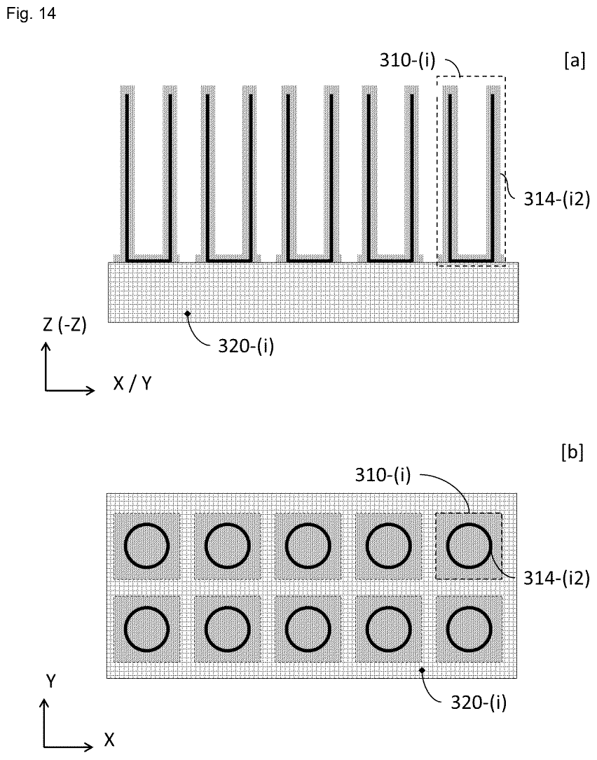

Diagrams 14[a] and 14[b] of FIG. 14 show, in the plane (X, Z) and the plane (X, Y), respectively, at least part of the interconnect component 300 in the process of being fabricated in sub-step 1610, according to some embodiments of the invention. In particular, diagrams 14[a] and 14[b] show a support substrate 320-(i) carrying micro-tubes 310-(i) in the process of being fabricated, each formed by a wall 314-(i2) resulting from the fabrication sub-step 1610. A micro-tube wall 314-(i2) may consist of a dielectric material part covered with a metal material part, corresponding respectively to the layer 314A and to the layers 314B and 314C of the wall 314 of a micro-tube 310-p of a fabricated interconnect component 300.

Advantageously, in embodiments in which a support substrate is a wafer, preparing at least part of the interconnect component 300 may comprise a sub-step 1612 of etching (or perforating) the support substrate perpendicularly, from the back face of the substrate to the support face, forming a plurality of micro-vias. Each etching may be carried out so as to open onto the inside of the micro-tubes.

Sub-step 1612 may consist of a sub-step of preparing the intermediate substrate 320 possibly present in part of the interconnect component 300. Sub-step 1612 may be implemented by a microelectronics process, such as the deep silicon etching process known as the BOSCH process, by a deep reactive ion etching (deep RIE) process, or else by a wet chemical etching process in the case of isotropic (that is to say non-crystalline) materials.

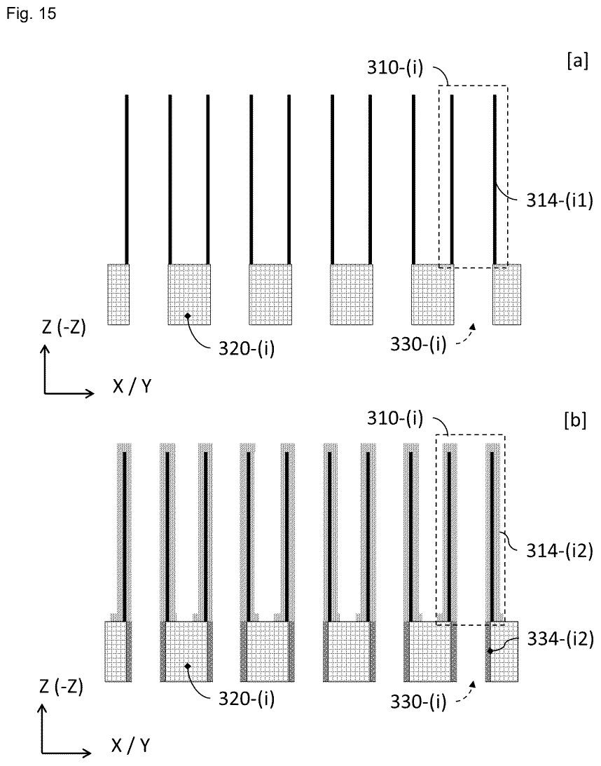

Diagram 15[a] of FIG. 15 shows, in the plane (X, Z), at least part of the interconnect component 300 in the process of being fabricated following sub-step 1612, according to some embodiments of the invention. In particular, diagram 15[a] shows a support substrate 320-(i) comprising a plurality of micro-vias 330-(i) and carrying a plurality of micro-tubes 310-(i) in the process of being fabricated, each formed by a wall 314-(i1) resulting from the fabrication sub-step 1604.

Advantageously, in embodiments in which the support substrate is a wafer, preparing at least part of the interconnect component 300 may comprise a sub-step 1614 of depositing a thin metal layer (or liner) on the inner wall (or edge or flank) of the micro-vias 330-(i). Such localized metallization may be carried out by electrochemical deposition, for example. In these variants of the invention, at least some of the micro-tubes 310-(i) formed on the support substrate 320-(i) may result from step 1610 of carrying out localized metallization of the micro-tubes.

Diagram 15[b] of FIG. 15 schematically shows, in a plane (X, Z), at least part of the interconnect component 300 in the process of being fabricated following sub-step 1614, according to some embodiments of the invention. In particular, diagram 15[b] shows a support substrate 320-(i) comprising a plurality of micro-vias 330-(i) with a wall 334-(i2), and carrying a plurality of micro-tubes 310-(i) in the process of being fabricated, each formed by a wall 314-(i2) resulting from the fabrication sub-step 1610

Advantageously, preparing at least part of the interconnect component 300 may comprise a sub-step 1616 of filling (injecting) a material into at least some of the micro-tubes 310-(i) and/or micro-vias 330-(i), with a propagation material. For example and without limitation, the filling may be injected (or inserted) from the back face of the support substrate 320-(i) forming at least part of the intermediate substrate 320. Such an injection material may be made from a polysilicon, an oxide or else notably a nitride.

Advantageously, a sub-step 1616 of filling a material into at least some of the micro-tubes and/or micro-vias may be carried out following a sub-step 1610 and/or a sub-step 1614 of metal deposition on the inner wall of the micro-tubes and micro-vias. Such a filling sub-step 1616 may be implemented for example using vacuum deposition equipment. In some exemplary embodiments, the filling sub-step 1616 may comprise filling with a liquid medium such as distilled and/or deionized water, via the deposition of a micro-drop of water to form a micro-lens. In this case, in order to keep the water in the micro-tube during assembly, a step of lowering the temperature of the component to freeze the water within the micro-tube for the time of the assembly may be implemented.

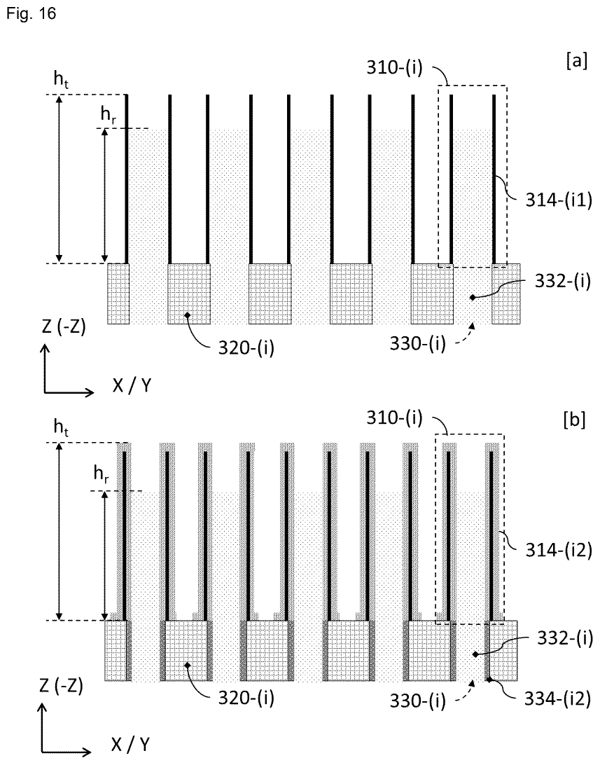

Diagrams 16[a] and 16[b] of FIG. 16 schematically show, in the plane (X, Z), at least part of the interconnect component 300 in the process of being fabricated in sub-step 1616, according to some embodiments of the invention. In particular, diagrams 16[a] and 16[b] show a support substrate 320-(i) comprising a plurality of micro-vias 330-(i) with or without a wall 334-(i2), and carrying a plurality of micro-tubes 310-(i) in the process of being fabricated, each formed by a wall 314-(i1) or 314-(i2) resulting from the fabrication sub-step 1604 or 1608, respectively. In diagrams 16[a] and 16[b], the plurality of micro-vias 330-(i) and the plurality of micro-tubes 310-(i) are filled with an injection material 332-(i) resulting from the fabrication sub-step 1616.

Advantageously, in embodiments in which the process comprises using two wafers as support substrates 320-(i) carrying micro-tubes 310-(i), preparing at least part of the interconnect component 300 may comprise a sub-step 1618 of bonding the two back faces of the wafers used to one another so as to form the intermediate substrate 320 comprising an interface 328. Such a bonding operation may be implemented by brazing, or else with or without a filler element. Such a bonding operation may notably be implemented by direct oxide bonding, or by direct metal bonding, or else by direct hybrid (that is to say oxide-metal) bonding. For example, the bonding operation may be implemented via a direct bonding technique after a chemical and mechanical polishing (CMP) operation, or after a surface activated bonding (SAB) treatment.

Steps 1200, 1400 and/or 1600, relating to the various fabricated components of the device, may furthermore comprise a sub-step of cutting at least part of the component in question, so as to obtain subsets of emission zones, micro-tubes and/or reception zones. In particular, such micro-tube cutting may be carried out so as to form vignettes of at least one micro-tube, in fields of different sizes so as to adapt to the number of waveguides required.

According to some embodiments, step 1800 of assembling the various components in the phase of fabricating the transmission device 10 may consist in cold-inserting the micro-tubes 310-(i) (fabricated during the fabrication of the interconnect component 300) into the assembly elements 116-n and/or 216-n (formed during the preparation of the photonic components). This insertion step may be implemented using “pick-and-place” equipment comprising a controlled press system and a precise alignment and placement system (precise meaning of the order of a micron or even a lower order).

During this cold-insertion step, the micro-tubes penetrate the malleable material so as to ensure optical sealing and electrical contact. It should be noted that the injection of the filler material in sub-step 1616 of assembling the interconnect component 300 may be applied such that it induces partial filling of the micro-tubes 310-(i) defined according to a maximum filling height hᵣ strictly less than the height hₜ of the micro-tubes in question. Such partial filling may make it possible notably to leave enough ‘free’ height (hₜ-hᵣ) of a micro-tube to penetrate the assembly elements of size hᵢ. Thus, in some embodiments, such a filling sub-step 1616 may comprise implementing a chemical mechanical polishing/planarization (CMP) step, or else implementing a selective etching step based on reactive gases.

The combined use of micro-tubes and coupling elements, and the cold-insertion step, make it possible to optimize the optical and possibly electrical coupling between the emitter component and the receiver component.

In addition, the cold insertion implemented in step 1800 of assembling the components may take into account a compressive force value of the order of a few hundredths of a gram to a few grams per micro-tube, taken into account in the compression operation. For example, a typical compressive force value for guaranteeing the quality of the contacts formed by the device 10 may be around 1 gram per micro-tube if the insertion is carried out into aluminium assembly elements, and around 0.1 gram per micro-tube if the insertion is carried out into assembly elements formed of a ductile material such as indium.

The total compressive force available or to be applied to the components for connecting (or coupling) all the objects of the optical assemblies of the device 10 may be determined depending on the number of micro-tubes to be inserted into the receiving pads. For a compression apparatus comprising a vertical force arm capable of supporting 400 kg, the cold insertion in the assembly step 1800 may, for example and without limitation, ensure the insertion of 400,000 to 4,000,000 micro-tubes into assembly elements. Such an assembly capacity makes it possible to obtain an improved device 10, and in particular a device that is dense, in terms of the number of optical and/or electro-optical transmission channels between an emissive matrix and a receiving matrix.

Those skilled in the art will readily understand that some steps or sub-steps of the process, illustrated notably in FIGS. 10 and 12, may be carried out simultaneously, sequentially, successively, independently or otherwise, and/or in a different order, for example in an order defined during the phase of designing the transmission device 10.

It should be noted that some features of the invention may have advantages when considered separately.

The process described above according to the embodiments of the invention may be implemented using various elements. In particular, the design phase and/or the physical fabrication phase may use hardware means, software means, or a combination of hardware and software, notably in the form of program code able to be distributed in the form of a program product, in various forms.

The invention is not limited to the embodiments described above by way of non-limiting example. It encompasses any variant embodiments that might be envisaged by those skilled in the art. Those skilled in the art will understand that the invention is not limited to the various components, to the various configurations, or to the various steps for fabricating the transmission device that have been described by way of non-limiting example. In particular, some embodiments of the invention may be combined.

1. A photonic device comprising an emitter component, configured to emit at least one emission signal (S₁) comprising an optical signal component, a receiver component, and an interconnect component between the emitter component and the receiver component, said interconnect component comprising at least one micro-tube designed to transmit said optical signal component coming from said emitter component to said receiver component, said at least one micro-tube comprising a wall and an internal medium designed to propagate said optical signal component, surrounded by the wall of the micro-tube, said wall being designed to separate the internal medium and an ambient medium in which said photonic device is immersed, said photonic device comprising at least one transmission and/or reception coupling element, said coupling element being configured to couple one end of a micro-tube to said emitter component or to said receiver component, said coupling element being made of a malleable metal material.

2. The photonic device according to claim 1, wherein said at least one emission signal (S₁) furthermore comprises an electrical signal component, the wall of a micro-tube comprising at least one metal part configured to propagate said electrical signal component coming from said emitter component to said receiver component.

3. The photonic device according to claim 1, wherein said interconnect component furthermore comprises an intermediate substrate comprising at least one micro-via in association with each micro-tube, said at least one micro-via being designed to transmit the optical signal component coming from the emitter component to said receiver component.

4. The photonic device according to claim 3, wherein said at least one emission signal (S₁) furthermore comprises an electrical signal component, and wherein said at least one micro-via comprises a metal wall configured to propagate said electrical signal component coming from said emitter component to said receiver component.

5. The photonic device according to claim 1, wherein said at least one micro-tube comprises a filler material chosen so as to optimize the propagation of the optical component of the signal to be transmitted.

6. The photonic device according to claim 3, wherein said at least one micro-via comprises a filler material chosen so as to optimize the propagation of the optical component of the signal to be transmitted.

7. The photonic device according to claim 1, wherein the dimensions of said interconnect component are of the order of a few micrometres to a few tens of micrometres.

8. The photonic device according to claim 1, wherein said interconnect component furthermore comprises a photonic interposer, said at least one micro-tube extending longitudinally between said emitter component and said photonic interposer, and/or between said photonic interposer and said receiver component.

9. A process for fabricating the photonic device according to claim 1, wherein the process comprises the following steps:
preparing an emitter component capable of emitting at least one emission signal (S₁) comprising an optical signal component, and preparing a receiver component, the emitter component and/or the receiver component comprising at least one coupling element made of a malleable metal material,
fabricating an interconnect component comprising at least one micro-tube, and
assembling said interconnect component between the emitter component and the receiver component, by cold-inserting said at least one micro-tube into said at least one coupling element; said process comprising fabricating said at least one micro-tube, said at least one micro-tube being capable of transmitting said optical signal component coming from said emitter component to said receiver component, said at least one micro-tube comprising a wall and an internal medium capable of propagating said optical signal component, surrounded by the wall of the micro-tube, said wall separating the internal medium and an ambient medium wherein said photonic device is immersed.

10. The process according to claim 9, wherein said assembly step comprises coupling the emitter component and/or the receiver component to one end of a micro-tube using at least one emission coupling element and/or at least one reception coupling element, said coupling comprising cold-inserting said at least one micro-tube of the interconnect component into said at least one emission and/or reception coupling element.

11. The process according to claim 9, wherein said step of fabricating the interconnect component comprises:
providing at least one support substrate,
fabricating said at least one micro-tube, on a support face of said support substrate,
implementing at least one etching of said support substrate perpendicularly so as to form at least one micro-via, from a back face of said support substrate to the support face, said at least one etching being carried out so as to open onto the inside of said at least one micro-tube.

12. The process according to claim 9, wherein said at least one emission signal (S₁) furthermore comprises an electrical signal component, and wherein said step of fabricating the interconnect component comprises depositing a metal layer on the wall of a micro-tube so that said wall comprises at least one metal part capable of propagating said electrical signal component coming from said emitter component to said receiver component.
